(19) United States
(12) Patent Application Publication
(10) Pub. No.: US 2024/0364281 A1
(43) Pub. Date: Oct. 31, 2024

(54) CLASS D-H PREAMPLIFIER AND CASCODED HIGH-VOLTAGE AMPLIFIER

(71) Applicant: Advanced Energy Industries, Inc., Denver, CO (US)

(72) Inventor: Donnie Herman, Olcott, NY (US)

(21) Appl. No.: 18/633,590

(22) Filed: Apr. 12, 2024

Related U.S. Application Data
(63) Continuation-in-part of application No. 18/309,421, filed on Apr. 28, 2023.

(51) Int. Cl. H03F 3/217; H03F 1/30; H03F 3/45; H03F 3/68

(52) U.S. Cl. CPC H03F 3/2171; H03F 1/303; H03F 3/45179; H03F 3/68; H03F 2200/168; H03F 2200/351; H03F 2200/78

(57) ABSTRACT

A cascoded high-voltage amplifier with Class D-H preamplifier is disclosed. The cascoded amplifier can include a chain of series-coupled low-voltage amplifiers, sometimes with a common gain, where an output of each low-voltage amplifier is coupled to an input of a next low-voltage amplifier, and inputs of adjacent low-voltage amplifiers are coupled via a feedforward connection, and optionally through an impedance component. In this way, a change in the input signal to the preamplifier can level shift the entire chain of low-voltage amplifiers through the feedforward connections. The gain of the cascoded high-voltage amplifier can be a function of the number of low-voltage amplifiers plus that of the Class D-H preamplifier, and a high-voltage output can be achieved without seeing high-voltage drops within the amplifier.

### CLAIM OF PRIORITY UNDER 35 U.S.C. § 120

The present Application for Patent is a Continuation-in-Part of patent application Ser. No. 18/309,421 entitled “Cascoded High-Voltage Amplifier” filed Apr. 28, 2023, pending, and assigned to the assignee hereof and hereby expressly incorporated by reference herein.

### FIELD OF THE DISCLOSURE

The present disclosure relates generally to power amplification. In particular, but not by way of limitation, the present disclosure relates to systems, methods and apparatuses for amplifiers with switched preamplifiers and multiple cascoded power amplifying cells.

### DESCRIPTION OF RELATED ART

Amplifiers are integral components in a wide range of electronic systems, serving to increase the power of a signal. They find application in numerous fields, including audio and video broadcasting, wireless communication, and even medical devices. The design and operation of amplifiers can vary greatly depending on the specific requirements of the application, such as the desired gain, frequency range, and power efficiency.

One common type of amplifier is the power amplifier, which is designed to deliver a large amount of power to a load, such as a speaker, antenna, or plasma processing chamber. Power amplifiers are typically classified into different classes (A, B, AB, C, D, etc.) based on their operating principle and efficiency. For instance, Class D amplifiers, also known as switching amplifiers, are known for their high efficiency, but they can see higher distortion than Class A, B, and AB amplifiers. On the other hand, Class H amplifiers are designed to improve efficiency by modulating the supply voltage according to the input signal, but they can be complex to implement.

The Class AB, or push-pull amplifier, uses an output pulled from between a switched connection to a high voltage rail and a switched connection to ground or an opposite polarity high voltage rail (see FIG. 1). The input signal alternately activates the first and second switches to thereby replicate the input signal via the pulling high and pulling low of the output signal, each half of a cycle amplified by a corresponding one of the two switches. For increased power, each of these two switches can be replaced by a series of switches 106, a “cascoded topology,” for instance as seen in FIG. 1, thereby multiplying the power handling capability proportional to the number of switches used. High-voltage components are used in this type of AB amplifier, which unfortunately leads to larger, costlier, and hotter systems than desired in some applications.

Although efforts have been made to improve the AB amplifier, for instance the cascoded FETs and Zener diodes in U.S. Pat. No. 10,511,262 and cascoded FETs in U.S. Pat. Nos. 4,697,155, 10,177,713, and 10,301,587. Such efforts still utilize mostly high-voltage components and thus cannot achieve a significant cost and size reduction. Some Class D amplifiers use feedback to control distortion at higher power, and at least one attempt even disengages feedback at lower powers to seek the best of both non-distorted high power and accuracy at lower powers (see U.S. Pat. No. 11,121,690). Other attempts have sought to bring greater linearity to Class D switching outputs, for instance, by providing multiple pulse-width modulated output levels as seen in U.S. Pat. No. 9,979,354. Japanese Patent No. 6046091 discloses multiple linear amplifiers for different RF protocols.

The cascoded topology seen in FIG. 2 uses a series of amplifiers to convert an input signal to an output signal, where feedback from the output signal was used by a feedback controller 108 to influence the signal provided to the first amplifier 102. A high voltage rail provides power to the last amplifier 106 in the chain. However, this high-voltage amplifier uses multiple high-voltage components, such as the feedback controller 108 and needs an optoisolator between the feedback loop and the first amplifier 102. Thus, even this design leaves room for improving a high-voltage amplifier.

### SUMMARY OF THE DISCLOSURE

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

In some aspects, the techniques described herein relate to an amplifier including: a switched preamplifier; and a power amplifier including: a first amplifying cell and a second amplifying cell; wherein the first amplifying cell is coupled between the switched preamplifier and the second amplifying cell.

In some aspects, the techniques described herein relate to a method of operating an amplifier including: receiving a low voltage at a switching preamplifier; controlling rails of the switching preamplifier according to the low voltage; and amplifying an output of the switching preamplifier to a high voltage via two or more low voltage amplifier cells.

In some aspects, the techniques described herein relate to a non-transitory, tangible computer readable storage medium, encoded with processor readable instructions to perform a method for amplification, the method including: controlling a switching preamplifier to apply gain to a low-voltage input signal via Class D amplification, variable power rails, or a blending of the two; and regulating power to two or more amplifying cells connected to an output of the switching preamplifier, the two or more amplifying cells having a switching speed commensurate with a switching speed of the switching preamplifier.

In one aspect, the disclosure describes series-connected amplifiers or variable DC sources that change their voltage concurrently in series. In some aspects, the amplifiers may be configured to provide a high-voltage output signal to a load. This high-voltage output capability may make the amplifiers suitable for applications requiring high voltage outputs, such as, but not limited to, audio amplification or power supply applications. Feedforward connections between amplifiers communicate an input signal upstream and this feedforward network eliminates the need for parallel high-voltage opto-couplers on each cell or stage. Because the cells are arranged in a cascode, and because each amplifier is controlled by voltage from a previous amplifier and also produces a voltage, the system can be referred to as a cascoded high-voltage amplifier or cascoded voltage-controlled-voltage-source high-voltage amplifier.

In one aspect, a cascoded amplifier is disclosed including a series of amplification cells arranged sequentially such that an output of an N^{th} cell in the chain is provided to an immediately following cell (e.g., both inputs of the immediately following cell) via a resistor network (e.g., two voltage dividers). The input of an N^{th} cell can be provided to an input of the immediately following cell to provide level shifting of one cell to the next via feedforward links. In other words, each cell's output is coupled to the input of the next two cells. In an embodiment, the resistor networks are selected so that every cell exhibits substantially a common gain, A (such as 2, 4, or 8), and via feedforward biases between adjacent cells, cause equal level shifting from cell to cell, thereby causing a final cell to provide a high-voltage amplified version of the input signal that is N*A times greater than the input signal. While the first cell can have a grounded input, all subsequent cells are floating. The resulting high voltage amplifier achieves N*A amplification without a high-voltage (e.g., greater than 50V) drop across components of the cascoded amplifier and without high-voltage isolation between the cells (e.g., no optoisolators are needed to isolate cells from each other). Said another way, this topology allows high voltage amplification using exclusively low-voltage components.

Some embodiments of the disclosure may be characterized as a high-voltage amplifier. The high-voltage amplifier can be a cascaded high-voltage amplifier in some embodiments. The high-voltage amplifier can include a voltage input, first and second amplifying cells, and an N^{th} amplifying cell. The voltage input can be configured to receive an input voltage. The first amplifying cell can comprise a first amplifier coupled to the voltage input via a first input and having a first output, and can be configured to amplify the input voltage with a first gain to provide an amplified version of the input voltage at the first output. The second amplifying cell can comprise a second amplifier having a second output and can be configured to amplify the first output by a second gain. The second amplifying cell has a first feedforward connection between the first input of the first amplifier and a first input of the second amplifier. The N^{th} amplifying cell can comprise an N^{th}-1 amplifier configured to output a high voltage version of the input voltage, wherein N is a number of amplifying cells, and wherein at least the second and N^{th} amplifying cells are provided power while being isolated from a grounded source of the power.

Other embodiments of the disclosure may also be characterized as an amplifier comprising a voltage input, a first variable DC source, a second variable DC source, and an N^{th} variable DC source. The voltage input can be configured to receive an input. The first variable DC source can be coupled to the voltage input and can have a first output. The first variable DC source can have a first gain, and can be configured to amplify the input voltage and to provide an amplified version of the input voltage at the first output. The second variable DC source can be configured to amplify the first output. The N^{th} variable DC source can be configured to amplify an output of an N^{th}-1 variable DC source and to output a high-voltage version of the input voltage. N is a number of variable DC sources in the amplifier. Feedforward connections between adjacent ones of the variable DC sources level shift subsequent variable DC sources in response to changes to the input voltage.

Other embodiments of the disclosure can be characterized as a method including receiving a low-voltage signal from a signal source at a first time; powering a chain of N low-voltage amplifiers via voltage regulators that are isolated from a power supply of the voltage regulators; amplifying the low-voltage signal via the chain of low-voltage amplifiers coupled in series to provide a high-voltage output signal to a load, wherein the second through N^{th}-1 low-voltage amplifiers are floating; receiving a change in the low-voltage signal from the signal source at a second time; and level shifting the low-voltage amplifiers, in response to the change, via feedforward connections between inputs of adjacent ones of the low-voltage amplifiers, to provide a correspondingly changed high-voltage output signal to the load.

According to an aspect of the present disclosure, the amplifier includes a switched preamplifier and a power amplifier. The power amplifier includes a first amplifying cell and a second amplifying cell. There is a feedforward connection between the first amplifying cell and the second amplifying cell, with the first amplifying cell being coupled between the switched preamplifier and the second amplifying cell.

According to other aspects of the present disclosure, the amplifier may include one or more of the following features. The switched preamplifier may have variable rails powering a switching amplifier cell. The switched preamplifier may be a Class D-H amplifier configured to adjust a blending of D and H modes (i.e., a blended D-H amplifier). The first amplifying cell may be coupled to a power regulator that is isolated from a power source. The switched preamplifier may have a voltage input below 50 volts and the power amplifier may have a voltage output above 100 volts or above 500 volts or above 1000 volts. A voltage across either of the first and second amplifying cells may be less than or equal to 50 volts. The feedforward connection may be between an input of the first amplifying cell and an input of the second amplifying cell. Outputs of the first and second amplifying cells may see a common current. The switched preamplifier may include a switched pair output stage. The first and second amplifying cells each may include at least one switch having a switching speed substantially the same or greater than a switching speed of the at least a pair of switches in the switched preamplifier. The amplifier may be configured to receive a low voltage pulsed input and generate a high voltage pulsed output. The amplifier may be configured to receive a low voltage analogue input and generate a high voltage analogue output. A filter may be arranged between a final amplifying cell in the power amplifier and an output of the power amplifier. The switched preamplifier may convert the low voltage analogue input to a pulse-width-modulated signal before providing it to the first amplifying cell. A voltage divider at an input of the second amplifying cell may bias an input of the second amplifying cell with a voltage that is part-way between the input and output of the second amplifying cell. An output of the first amplifying cell may be coupled to an input of the second amplifying cell via an impedance component. The first and second amplifying cells may have a same gain.

According to another aspect of the present disclosure, a method of operating an amplifier includes receiving a low voltage at a variable-amplitude switching preamplifier, amplifying an output of the variable-amplitude switching preamplifier via two or more switching amplifier cells with a feedforward connection therebetween, and providing a high voltage version of the low voltage at an output of the two or more switching amplifier cells.

According to other aspects of the present disclosure, the method may include one or more of the following features. The low voltage may be linear, and the method may further include converting the low voltage to a variable amplitude pulse-width modulated voltage in the variable-amplitude switching preamplifier. The method may further include filtering an output of each of the two or more switching amplifier cells. The method may further include amplifying a pulsed voltage and the two or more switching amplifier cells may be linear.

According to another aspect of the present disclosure, an amplifier includes a switched preamplifier and a power amplifier. The power amplifier includes a first amplifying cell coupled to a second cell. The first amplifying cell is coupled to the preamplifier and is configured to amplify an output of the preamplifier by a first gain. The second cell is coupled to the first amplifying cell and is configured to amplify an output of the first amplifying cell. The second amplifying cell has a first feedforward connection between the first amplifying cell and the second amplifying cell.

According to another aspect of the present disclosure, an amplifier includes a switched preamplifier and a power amplifier. The power amplifier includes a first amplifying cell coupled to a second cell. The first amplifying cell is coupled to the preamplifier and is configured to amplify an output of the preamplifier by a first gain. The second cell is coupled to the first amplifying cell and is configured to amplify an output of the first amplifying cell. The second amplifying cell has a first feedforward connection between the first amplifying cell and the second amplifying cell. The switched preamplifier is a Class D-H amplifier configured to adjust a blending of D and H modes (i.e., a blended D-H amplifier).

According to another aspect of the present disclosure, an amplifier includes a switched preamplifier and a power amplifier. The power amplifier includes a first amplifying cell coupled to a second cell. The first amplifying cell is coupled to the preamplifier and is configured to amplify an output of the preamplifier by a first gain. The second cell is coupled to the first amplifying cell and is configured to amplify an output of the first amplifying cell. The second amplifying cell has a first feedforward connection between the first amplifying cell and the second amplifying cell. The switched preamplifier comprises variable rails.

According to other aspects of the present disclosure, the amplifier may include one or more of the following features. The second amplifying cell may be coupled to a power regulator that is isolated from a power source. The switched preamplifier may have a low voltage input and the power amplifier may have a high voltage output. A voltage across either of the first and second amplifying cells may be less than or equal to 50 volts. The first feedforward connection may be between an input of the first amplifying cell and an input of the second amplifying cell. Outputs of the first and second amplifying cells may see a common current. The switched preamplifier may comprise at least a pair of switches in parallel. The first and second amplifying cells each may comprise at least one switch having a switching speed substantially the same as a switching speed of the at least a pair of switches in the switched preamplifier. The switched preamplifier may comprise variable rails. The switched preamplifier may be a Class D-H amplifier configured to adjust a blending of D and H modes. A voltage divider may bias a first input of the first voltage-controlled voltage source with a voltage that is part-way between the input and output of the voltage source. An output of the first amplifying cell may be coupled to an input of the second amplifying cell via an impedance component.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1 illustrates a common topology for a cascoded A-B amplifier known in the art;

FIG. 2 illustrates a cascoded amplifier addressing certain issues identified in known cascoded A-B amplifier topologies;

FIG. 3 illustrates a generalized embodiment of a cascoded high-voltage amplifier that converts a low voltage input signal to a high-voltage output signal using N series-coupled low voltage cells;

FIG. 4 illustrates another embodiment of a cascoded high-voltage amplifier;

FIG. 5 illustrates another embodiment of a cascoded high-voltage amplifier showing exemplary resistance values and input and output voltages of cascoded amplifiers;

FIG. 6 illustrates an embodiment of a low-voltage amplifier using a differential pair of transistors for gain;

FIG. 7 illustrates a method of amplifying a low voltage to a high voltage;

FIG. 8 illustrates a method of amplifying a low voltage to a high voltage;

FIG. 9 illustrates an embodiment of a generic low-voltage amplifier that can be used in a chain of cells as part of a cascoded high-voltage amplifier;

FIG. 10A illustrates an amplifier for linear signals having a Class D preamplifier and a cascoded power stage comprising two or more Class D amplifiers;

FIG. 10B illustrates an amplifier for linear signals having a Class D-H preamplifier and a cascoded power stage comprising two or more Class D amplifiers;

FIG. 11 illustrates another amplifier for linear signals having a Class D-H preamplifier and a cascoded power stage comprising two or more Class D amplifiers;

FIG. 12A illustrates an amplifier for pulsed signals having a Class D preamplifier and a cascoded power stage comprising two or more linear amplifiers;

FIG. 12B illustrates an amplifier for pulsed signals having a Class D-H preamplifier and

a cascoded power stage comprising two or more linear amplifiers;

FIG. 13 illustrates another amplifier for pulsed signals having a Class D-H preamplifier and a cascoded power stage comprising two or more linear amplifiers;

FIG. 14 illustrates another amplifier for linear signals having a Class D-H preamplifier and a cascoded power stage comprising two or more Class D amplifiers;

FIG. 15 illustrates another amplifier for pulsed signals having a Class D-H preamplifier and a cascoded power stage comprising two or more linear amplifiers;

FIG. 16 illustrates a timing chart for a Class D-H preamplifier in a blended state that is primarily linear;

FIG. 17 illustrates a timing chart for a Class D-H preamplifier in a blended D-H state;

FIG. 18 illustrates a timing chart for a Class D-H preamplifier in a Class D state;

FIG. 19A illustrates a Class D-H preamplifier with a first arrangement of performance mode selectors;

FIG. 19B illustrates a Class D-H preamplifier with a second arrangement of performance mode selectors;

FIG. 20 illustrates an embodiment of a Class D-H preamplifier configured for operating on linear signals;

FIG. 21 illustrates an embodiment of a Class D-H preamplifier configured for operating on pulsed signals;

FIG. 22 illustrates another amplifier for linear signals having a Class D-H preamplifier and a cascoded power stage comprising two or more Class D amplifiers;

FIG. 23 illustrates another amplifier for pulsed signals having a Class D-H preamplifier and a cascoded power stage comprising two or more linear amplifiers;

FIG. 24A illustrates an amplifying cell with a low-voltage Class D amplifier;

FIG. 24B illustrate an amplifying cell with a low-voltage Class D amplifier comprising a PWM converter and a switching output stage;

FIG. 25A illustrates an amplifying cell with a low-voltage Class D amplifier;

FIG. 25B illustrate an amplifying cell with a low-voltage Class D amplifier comprising a PWM converter and a switching output stage;

FIG. 26 illustrates another amplifier for linear signals having a Class D-H preamplifier and a cascoded power stage comprising two or more Class D amplifiers;

FIG. 27A illustrates an amplifying cell with a low-voltage linear amplifier;

FIG. 27B illustrate an amplifying cell with a low-voltage linear amplifier comprising a three-state comparator and a switching output stage;

FIG. 28A illustrates an amplifying cell with a low-voltage linear amplifier;

FIG. 28B illustrate an amplifying cell with a low-voltage linear amplifier comprising a three-state comparator and a switching output stage;

FIG. 29 illustrates another amplifier for linear signals having a Class D-H preamplifier and a cascoded power stage comprising two or more linear amplifiers;

FIG. 30A illustrates a low-voltage amplifier with two ladders of parallel capacitors to enhance switching speed;

FIG. 30B illustrates a timing chart corresponding to the circuit of FIG. 30A;

FIG. 31 illustrates a method of operating an amplifier;

FIG. 32 illustrates a method of operating an amplifier on linear signals;

FIG. 33 illustrates a method of operating an amplifier on pulsed signals;

FIG. 34 illustrates a method of operating an amplifier; and

FIG. 35 illustrates an embodiment of a Class D-H amplifier or preamplifier.

### DETAILED DESCRIPTION

Prior to describing the embodiments in detail, it is expedient to define terms as used in this document.

The word “exemplary” is used herein to mean “serving as an example, instance, or illustration.” Any embodiment described herein as “exemplary” is not necessarily to be construed as preferred or advantageous over other embodiments.

The flowcharts and block diagrams in the following Figures illustrate the architecture, functionality, and operation of possible implementations of systems, methods and computer program products according to various embodiments of the present disclosure. In this regard, some blocks in these flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the amplifier in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The amplifier may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, components, and/or groups but do not preclude the presence or addition of one or more other features, integers, steps, operations, elements, components, and/or groups thereof. As used herein, the term “and/or” includes any and all combinations of one or more of the associated listed items, and may be abbreviated as “/”.

Embodiments of the disclosure are described herein with reference to illustrations that are schematic illustrations of idealized embodiments (and intermediate structures) of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

For the purposes of this disclosure, “coupled to” means an electrical path between two nodes, regardless of the impedance of that path and whether current passes through one or more impedance components between the two nodes. For instance, an output of a low-voltage amplifier may be coupled to an input of a next or subsequent or adjacent low-voltage amplifier whether or not this electrical path includes an impedance component such as a resistor.

For the purposes of this disclosure, a voltage-controlled voltage source, can include, but is not limited to, an amplifier, class D amplifier, variable power source or supply, variable DC source, DC-DC converter, signal booster, op amp, differential pair, or symmetrical circuit.

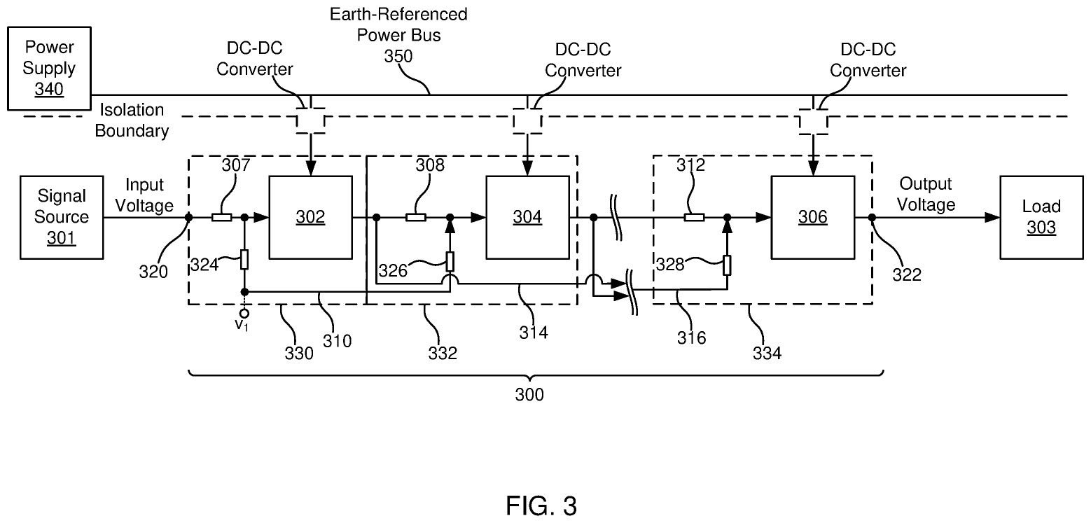

FIG. 3 illustrates a generalized embodiment of a cascoded high-voltage amplifier that converts a low voltage input signal to a high-voltage output signal using N series-coupled low-voltage amplifiers. N is a total number of low-voltage amplifier cells in the cascoded high-voltage amplifier 300. Traditional amplifiers, even using a cell-based approach, often use a voltage divider or similar topology to provide feedback to each cell, and these voltage dividers use high voltage (i.e., expensive and difficult to source) components, such as high voltage resistors, when an amplifier for high voltage is designed. Thus, a traditional amplifier's output is limited by the components therein. The cell-based approach used herein, along with the use of low-voltage amplifiers and corresponding low-voltage components, allows a nearly infinite number of cells to be stacked to achieve any output voltage. In other words, low voltage components can be used whether the output voltage is 500V or 50,000V, thereby providing a scalability not seen in the art. This is largely possible due to the use of feedforward connections to control level shifting and replace traditional opto-isolators and the allowance of all but the first and last cells to float.

As noted, the low-voltage amplifiers 302, 304, 306, other than the first and last or N^{th}, are floating. Each low-voltage amplifier 302, 304, 306 is also powered or biased by an earth-referenced power supply. For instance, in FIG. 3, a power supply 340 provides an earth-referenced power bus 350 with voltage such as 15V, where this earth-referenced power bus 350 is isolated from the cascoded high-voltage amplifier 300 via an isolation boundary. In some embodiments, the isolation boundary may be embodied in transformer, for instance as part of DC-DC converters or regulators, though other forms of isolation can also be implemented. The floating low-voltage amplifiers and the earth-referenced power supply that is isolated from the low-voltage amplifiers, along with a feedforward connection 310, 314, 316 between inputs of adjacent low-voltage amplifiers 302, 304, 306, allows a change in the input signal to the cascoded high-voltage amplifier 300 to level shift the entire chain of low-voltage amplifiers 302, 304, 306. In other words, a change to an input to the cascoded high-voltage amplifier 300 propagates through the entire cascoded high-voltage amplifier 300 with little if any delay or latency. At the same time, the floating nature of all but the first and last (or N^{th}) low-voltage amplifiers means that voltage differences between low-voltage amplifiers can be limited to “low voltage” such as, less than or equal to 50V, or only using components tailored to or rated to up to 50V. This allows most if not all of the cascoded high-voltage amplifier 300 to be constructed using common and inexpensive off-the-shelf low voltage components, yet achieve high voltage amplification (e.g., 1V in and 60V out, or 1V in and 120V out, or 1V in and 1 KV out, etc.).

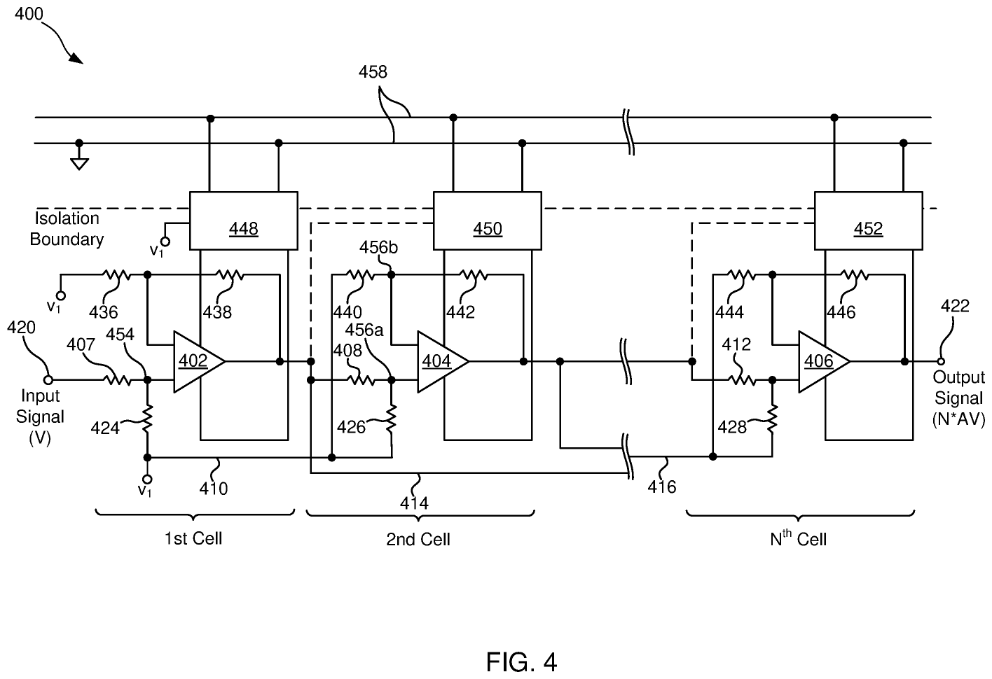

In some embodiments, each low-voltage amplifier 302, 304, 306 can have at least one input that is biased or controlled by an impedance network (having at least two impedance components in FIG. 3). For instance, in FIG. 4, each impedance network includes four resistors. The combination of a low-voltage amplifier, the impedance network, and a feedforward connection can form a low-voltage amplifier cell, of which a first 330, a second 332, and an N^{th} 334 (or last) are shown in FIG. 3-though some number of optional additional cells are not shown for the sake of simplicity. At a minimum, a cascoded high-voltage amplifier can include two cells and thus two amplifiers, though at least three are shown in FIG. 3. The number of cells and low-voltage amplifiers is not limiting, though cost, size, and complexity may steer designers toward a minimum number, which the inventor believes is achieved when each cell has a gain of 2.

Like the low-voltage amplifiers other than the first and N^{th} or last, the low-voltage amplifier cells, except the first and N^{th} or last, are floating. This, along with being isolated from the power supply 340, and the feedforward connections 310, 314, 316, means that the cascoded high-voltage amplifier 300 can respond to changes in input signal using low voltage cells. In other words, the impedance networks and feedforward connections can also use components tailored for low voltage operation or rated up to 50V, which are often off-the-shelf and low-cost components.

Additionally, it should be noted that since the voltage drop across any one low-voltage amplifier 302, 304, 306 or low-voltage amplifier cell 330, 332, 334 is low voltage (i.e., less than or equal to 50V), power dissipation is relatively low and evenly distributed across the cascoded high-voltage amplifier 300. In the case where the chain of cells gets too long in a certain direction, for instance, from a packaging standpoint, the chain can follow a u-shaped or s-shaped path to maintain a compact package. Further, circuit boards can be stacked in order to add even more cells while still maintaining a relatively compact overall high-voltage amplifier package.

The discussion now turns to additional details of the embodiment shown in FIG. 3 that help illuminate operation of the cascoded high-voltage amplifier without limiting a cascoded high-voltage amplifier more generally. The cascoded high-voltage amplifier 300 can include a voltage input 320 that may be a part of the first cell 330 or precede it. The voltage input 320 can be configured for coupling to a signal source 301 and is configured to receive an input voltage or input signal from the signal source 301. In some instances, an input voltage or input signal at the voltage input 320 can be a DC signal, while in others it can be an AC, pulsed DC, or arbitrary waveform. In other words, any voltage signal can be received at the voltage input 320 and amplified by the cascoded high-voltage amplifier 300. In this same vein, the signal source 301 should not be considered limiting of the cascoded high-voltage amplifier 300. Similarly, high and low frequency input voltages or signals can be implemented at the voltage input 320.

A voltage output 322 for the cascoded high-voltage amplifier 300 may or may not be a part of the last or N^{th} amplifier cell 334, and the voltage output 322 can be configured for coupling to a load 303 such as a speaker's voice coil, a digital circuit on a circuit board, an electrode in a plasma processing chamber, or the rotor or stator of an electrical motor, to name just a few non-limiting examples. In other words, the cascoded high-voltage amplifier 300 can be coupled between a signal source 301, and a load 303. Electrical connections well known to those of skill in the art can be made between (1) the signal source 301 and the cascoded high-voltage amplifier 300, and (2) between the cascoded high-voltage amplifier 300 and the load 303.

A high-voltage signal at the voltage output 322 can be an amplified version of the input signal at the voltage input 320, where a ratio of the output voltage over the input voltage, or the output signal over the input signal, or the signals at the voltage output 322 over that at the voltage input 320, can be called the amplifier gain. The amplifier gain is larger than a gain of any one of the low-voltage amplifier cells 330, 332, 334, and in many cases will be a sum of the gains of each of the low-voltage amplifier cells 330, 332, 334. In other words, a last or N^{th} low-voltage amplifier cell 334 in the chain, can include an N^{th} low-voltage amplifier 306 configured to output a high-voltage version of the input voltage.

The low-voltage amplifiers 302, 304, 306, can be, but are not limited to, a variable DC source, class D amplifier, variable power source or supply, voltage-controlled voltage source, DC-DC converter, signal booster, op amp, differential pair, symmetrical circuit, etc. In some cases, the low-voltage amplifiers 302, 304, 306 can be voltage sources, though current and power sources can also be implemented. It should also be understood that the low-voltage amplifiers 302, 304, 306 are not limited in response time, and can therefore provide low-latency signal tracking of pulsed DC, AC, and arbitrary waveforms, to name a few. In some cases, digital amplifiers can be used for the low-voltage amplifiers 302, 304, 306 where higher frequency input signals are used (e.g., greater than 5 MHz). In some cases, the low-voltage amplifiers 302, 304, 306 can be replaced with high-voltage amplifiers, such as those using components rated to greater than 50V. These situations may be seen where an especially large output voltage is desired.

In some cases, the first low-voltage amplifier 302 is different than the remaining low-voltage amplifiers 304, 306 or may not even be an amplifier. For instance, a buffer or other device having a gain of 1 could be used in place of the low-voltage amplifier 302. Said another way, the first amplifying cell 330 has a gain of 1 and subsequent amplifying cells have a gain greater than 1. Similarly, the low-voltage amplifiers 302, 304, 306 may have the same gain, while in other situations different gains may be used. In one embodiment, the second through last or N^{th} low-voltage amplifier 304, 306 have a gain of 2, while in another embodiment, all of the low-voltage amplifiers 302, 304, 306 have a gain of 2.

Each low-voltage amplifier cell 330, 332, 334 can have an input and an output. The first low-voltage amplifier cell 330 can be configured to amplify the input voltage with a first gain to provide an amplified version of the input voltage at the first output of the first low-voltage amplifier 302, which can be provided to an input of the second low-voltage amplifier cell 332. The second low-voltage amplifier cell 332 can include a second low-voltage amplifier 304 configured to amplify the first output by a second gain. The first low-voltage amplifier cell 330 can include a first feedforward connection 310 between the first input of the first low-voltage amplifier 302 and a first input of the second low-voltage amplifier 304. The first input of the second low-voltage amplifier 304 can be formed by a sum the output of the first low-voltage amplifier 302 and the first feedforward connection 310. For instance, this summing can be performed by a voltage divider comprising impedance components 308 and 326. In an embodiment, the output of the first low-voltage amplifier 302 can be coupled to the first input of the second low-voltage amplifier 304, and the input of the first low-voltage amplifier 302 can be coupled to the first input of the second low-voltage amplifier 304. This coupling can be made via a voltage divider such that the second low-voltage amplifier 304 is at a voltage less than the output of the first low-voltage amplifier 302 but greater than the input of the first low-voltage amplifier 302. Said another way, the output of the first low-voltage amplifier 302 is coupled to the input of the second low-voltage amplifier 304 via an impedance component 308, such that voltage actually drops between an output of one low-voltage amplifier and an input of a next low-voltage amplifier. Thus, while the overall cascoded high-voltage amplifier 300 amplifies the input signal at input voltage 320, voltage actually drops between low-voltage amplifiers.

As noted, the first low-voltage amplifier 302 or low-voltage amplifier cell 330 can be referenced to ground. FIG. 3 shows the first feedforward connection 310 being optionally held at voltage V₁, which in some cases is ground. However, more importantly, the first feedforward connection 310 can be held to whatever voltage, V₁ the signal source 301 is referenced to, which may be ground, but may also be some non-zero voltage.

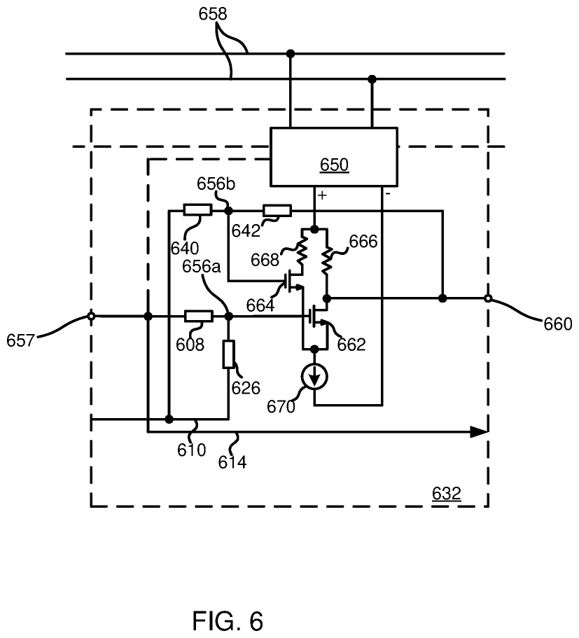

Each feedforward connection 310, 314, 316 may pass through an impedance component (e.g., 326, 328) in route to an input of a next low-voltage amplifier. Similarly, each output of a low-voltage amplifier 302, 304, 306 or low-voltage amplifier cell 330, 332, 334 may pass through an impedance component (e.g., 308, 312) in route to the input of the next low-voltage amplifier. Said another way, each low-voltage amplifier except the N^{th} or last one, can be coupled to a next or next adjacent low-voltage amplifier via an impedance component. The impedance components can include resistors or other resistive devices, though reactive components and components having both resistive and inductive components could also be implemented. In other terms, devices seeing a voltage drop can be implemented as the impedance components so long as they are selected to achieve a desired voltage drop from low-voltage amplifier output to low-voltage amplifier input that achieves a desired gain across a respective low-voltage amplifier cell (i.e., from one low-voltage amplifier output to an output of a next low-voltage amplifier). The impedance components 307, 324, 308, 326, 312, 328 can be part of impedance component networks, one impedance component network for each low-voltage amplifier cell 330, 332, 334 or each low-voltage amplifier 302, 304, 306. In FIG. 3 the impedance component network comprises two impedance components, though more could be implemented as shown in FIG. 4. It should be appreciated that although an impedance component network is shown in FIGS. 3 and 4, in certain embodiments, such an impedance component network may not be needed (e.g., see FIG. 6).

Isolation, and thus the ability of all but the first and last or N^{th} low-voltage amplifier cells to be floating, is an important feature that allows the low-voltage amplifier gains to sum and generate a high-voltage output. As noted earlier, the low-voltage amplifier cells 332, 334, except the first low-voltage amplifier cell 330 are each provided with power isolated from a grounded source of the power (e.g., power supply 340). In other words, all but a first low-voltage amplifier cell 330 in the chain is floating and receives power from DC-DC converters that are isolated or include isolation from, the power supply 340. Packaging for the cascoded high-voltage amplifier 300 may also support the isolation boundary, for instance a PCB without any conductive traces that cross the isolation boundary, or a PCB with elongated slits formed therein in a zigzagging pattern may reduce a cross section of the PCT spanning the isolation boundary thereby increasing dielectric resistance at the isolation boundary. In FIG. 3 one sees that each low-voltage amplifier cell 330, 332, 334 receives power from an earth-referenced power bus 350, and is also isolated from the earth-referenced power bus 350 and the source of power to the earth-referenced power bus 350 (e.g., the power supply 340). Although not explicitly illustrated, these isolated DC-DC regulators can be regulated such that a specific voltage is provided to each of the low-voltage amplifiers 302, 304, 306. Interestingly, the earth-referenced power bus 350 does not need to be high voltage (e.g., greater than 50V). For instance, if the input signal is 10V and the gain of each low-voltage amplifier is 2 or 20V, then a 25V earth-referenced power bus 350 could be used, and with enough low-voltage amplifier cells, the output could be many hundreds or even thousands of volts. For instance, 50 low-voltage amplifier cells would enable a 1000V output despite the earth-referenced power bus 350 being a mere 25V. As those of skill in the art will appreciate, the ability to achieve high voltage outputs with only low-voltage rails/buses and power supplies is a huge cost, size, and complexity advantage over the prior art.

Further, feedforward connections 310, 314, 316 between adjacent low-voltage amplifier cells 330, 332, 334 level shift the entire chain of low-voltage amplifier cells 330, 332, 334 without high-voltage isolation (such as optoisolators) along the feedforward connections 310, 314, 316. At the same time, isolation, floating cells, and the feedforward connections enable the cascoded high-voltage amplifier 300 is able to avoid or minimize use of high-voltage components and high-voltage isolation for a cooler-running and more compact form factor than is known in the art. What is more, by distributing amplification duties across N low-voltage amplifier cells, this disclosure more evenly achieves spatial distribution of thermal effects thereby avoiding hot spots in the cascoded high-voltage amplifier 300. Further, by removing optoisolators, the disclosure removes delays associated with signals that have to pass through optoisolators, thus making the cascoded high-voltage amplifier 300 more responsive to respond to input signals and transients.

Each low-voltage amplifier cell 330, 332, 334 can be configured to amplify an input voltage to that cell (in the case of all but the first low-voltage amplifying cell, this would be the output of the previous low-voltage amplifier cell). In some cases, all low-voltage amplifier cells 330, 332, 334 can have the same gain, referred to as A. In other cases, different low-voltage amplifier cells 330, 332, 334 may have different gains, for instance the first low-voltage amplifier cell 330 can have a gain B and the remaining low-voltage amplifier cells 332, 334 can have the gain A. The gain A, whether equal to B or not, can equal 2. However, the gain A (and optionally B as well) can be greater than 2 and in some cases can be an exponential of 2 (i.e., 2^{C}, where C is a positive integer), such that A (and optionally B) can equal 2, 4, 8, 16, etc. In some embodiments, the gain A (and optionally B) can equal 2^{C} and be less than a ratio of the output voltage over the input voltage. For instance, where the input voltage is 1V and the output voltage is 500V, C can be any positive integer such that 2^{C}<500/1 (i.e., C is a positive integer less than 9) and hence there could be up to 256 amplifying cells (2⁹). In other words, the first and second gain are equal to 2^{C} and less than the output voltage/the input voltage, where C is a positive integer. Regardless of the gain of each low-voltage amplifier cell 330, 332, 334 or the number N of low-voltage amplifier cells, the serial topology of the low-voltage amplifier cells 330, 332, 334 means that a common current is seen at the output of each low-voltage amplifier 302, 304, 306.

The number N of low-voltage amplifier cells 330, 332, 334 is not limited, but preferably will be equal to a total gain of the cascoded high-voltage amplifier 300 divided by at least a maximum voltage to be seen across any given low-voltage amplifier cell 330, 332, 334. For example, where a 1000V output is desired from a 1V input, and 50V is considered the desired cutoff for each cell to be considered “low voltage”, at least 20 low-voltage amplifier cells would be used. However, in some embodiments, this same topology can apply to situations where some or all of the low-voltage amplifier cells may not be considered low voltage, for instance, where a voltage across each cell is 75V, or 250V, or some other higher valuer above 50V. Such a compromise of the low voltage nature may be worthwhile for higher output voltage embodiments of the cascoded high-voltage amplifier 300.

FIG. 4 illustrates an embodiment of a cascoded high-voltage amplifier where each low-voltage amplifier is biased by a resistor network. In this embodiment, the low-voltage amplifiers are implemented as op amps 402, 404, 406, biased by a resistor network, each op amp 402, 404, 406 plus 4-piece resistor network forming an amplifying cell. Each op amp 402, 404, 406 has two inputs and an output. Inputs of adjacent op amps 402, 404, 406 are coupled via a feedforward connection 410, 414, 416, and each op amp's output is coupled to an input of a next or subsequent op amp 402, 404, 406, through a resistor, except the last or N^{th} op amp 406, whose output is, or is connected to, the output 422 of the cascoded high-voltage amplifier 400. More specifically, a first input 454 of the first op amp 402 is coupled to both the first and second inputs 456a and 456b of the second op amp 404. The first feedforward connection 410 to the first input 456a of the second op amp 404 passes through resistor 426, while the first feedforward connection 410 to the second input 456b of the second op amp 404 passes through resistor 440. The output of the first op amp 402 passes through resistor 408 to the first input 456a of the second op amp 404 and also couples to the second feedforward connection 414.

During steady state operation, both inputs of each op amp 402, 404, 406 are equal or balanced and the gain of each op amp 402, 404, 406 is set via the corresponding resistor network (e.g., 407, 424, 436, 438 for the first op amp 402 and 408, 426, 440, 442 for the second op amp 404). Each resistor network is formed from two voltage dividers, one for each of the op amp inputs. While the feedforward connection 410 of the first low-voltage amplifier cell is ground referenced or referenced to V₁, all subsequent feedforward connections such as the second feedforward connection 414 and the N^{th} feedforward connection 416, are floating.

Where the gain of each op amp 402, 404, 406 is equal, the resistor networks can use the same resistance values. For instance, where a gain of 2 is used, the resistors of the first and second low-voltage amplifier cells can be as follows, where R is an arbitrary resistance: 436, 407, 440, 408=R and 438, 410, 442, and 426=2R. Although this example uses a relationship between resistors of 2R to obtain a gain of 2, other ratios can also be used to achieve other gains. Additionally, the resistor values for the entire resistor network of a low-voltage amplifier cell can be adjusted while maintaining a ratio and thus a gain in order to optimize bandwidth and efficiency. For instance, reducing resistor values gives greater bandwidth but lower efficiency. In one non-limiting example, the resistors 436, 407, 440, 408 can equal 1000 Ohms, while the resistors 438, 410, 442, and 426 can equal 2000 Ohms.

Each op amp 402, 404, 406 can be biased by a DC-DC converter 448, 450, 452, where each of these DC-DC converters 448, 450, 452 are isolated from an earth-referenced power bus 458. For instance, each DC-DC converter 448, 450, 452 can use a transformer to both down convert voltage from the earth-referenced power bus 458 as well as provide isolation from the ‘high-voltage’ side of the isolation boundary (it should be noted that the earth-referenced power bus 458 may also be low voltage). The first earth-referenced power bus 448 may be referenced to voltage V₁ (e.g., ground) and thus may not need internal isolation structures such as a transformer. Although a transformer is one means of converting the earth-referenced power bus voltage to a voltage for use within each of the low-voltage amplifier cells, other conversion topologies such as switching converters, etc. can also be used. The first feedforward connection 410 as well as a second input to the first low-voltage amplifier cell are both held to voltage V₁, or the same reference voltage as the first DC-DC converter 448. In some cases, V₁ is ground, but this is not required. Accordingly, the first low-voltage amplifier cell and the first low-voltage amplifier 402 are not floating, but rather have a fixed reference voltage, V₁. The remaining low-voltage amplifier cells and low-voltage amplifiers except the last or N^{th} are floating. The last or N^{th} low-voltage amplifier cell and low-voltage amplifier are referenced to a load once coupled thereto.

The second through N^{th} low-voltage amplifier cells can include an optional bias line between a respective one of the DC-DC converters 450, 452 and a common node (e.g., the common node for the first or second low-voltage amplifier cells is effectively the output of the first low-voltage amplifier 402 and the node preceding the resistance 408). These optional bias lines enable a given DC-DC converter to bias a corresponding low-voltage amplifier relative to the common node preceding that low-voltage amplifier.

In this embodiment, a first two cells and an N^{th} cell are shown for simplicity, but those of skill in the art will appreciate that any number of two or more low-voltage amplifier cells may be implemented in the cascoded high-voltage amplifier based on the teachings in FIG. 4 (i.e., N is equal to or greater than 2).

Assuming a constant gain A for all of the cells, the output signal can be N*A times larger than the input signal, where N is the number of low-voltage amplifier cells in the cascoded high-voltage amplifier 400.

Although FIG. 4 uses op amps as an illustrative embodiment of the low-voltage amplifiers found in the cascoded high-voltage amplifier, other amplifiers can also be used, such as the discrete transistor-based amplifiers shown for example in FIG. 6.

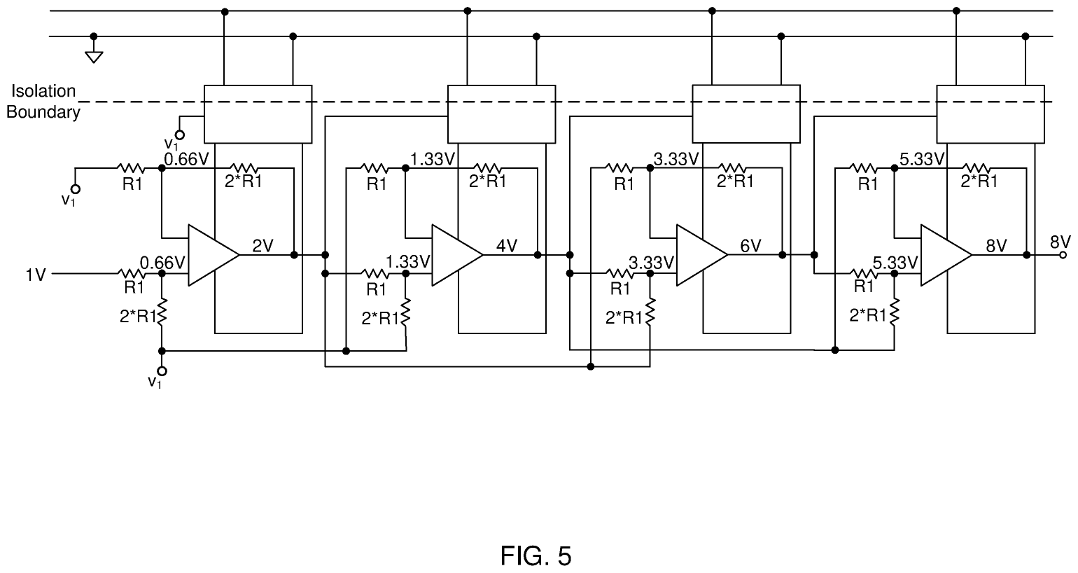

FIG. 5 shows illustrative voltages and resistances for components of the cascoded high-voltage amplifier of FIG. 4 where N=4. One will notice that a gain of 2 has been selected for each of the low-voltage amplifier cells leading to a total gain of 8 for the cascoded high-voltage amplifier. Accordingly, no more than 2V is seen between any low-voltage amplifier cells and thus low voltage components can be used throughout. The gain of each low-voltage amplifier cell is determined by the resistance values selected for the resistor network of each low-voltage amplifier cell. As seen, each resistor network includes two resistors having resistance R1, and two having resistance R2 or 2*R1. In one non-limiting example, R1=10,000 Ohms and R2=20,000 Ohms.

For the purposes of clarity, one will note that the gain of a low-voltage amplifier cell and the gain of a low-voltage amplifier are different. For instance, the gain of each low-voltage amplifier cell is 2, and the gain of each low-voltage amplifier depends on the low-voltage amplifier in question.

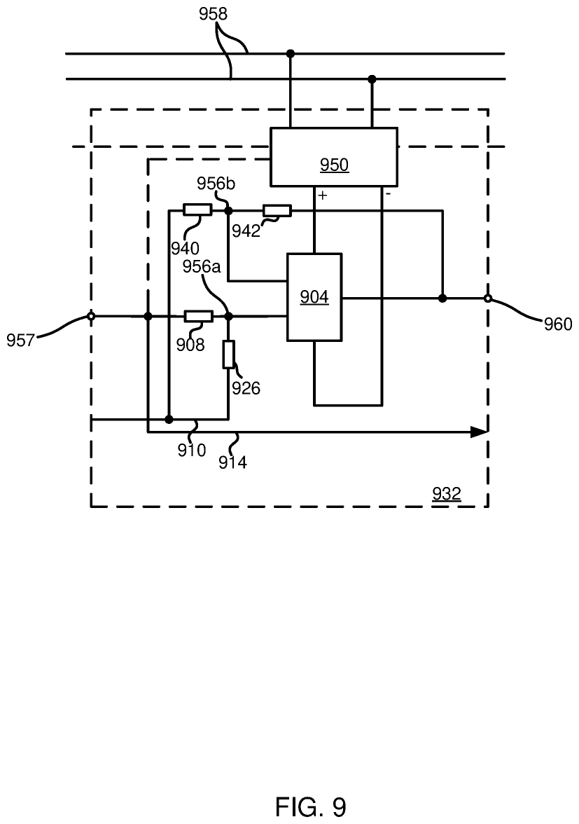

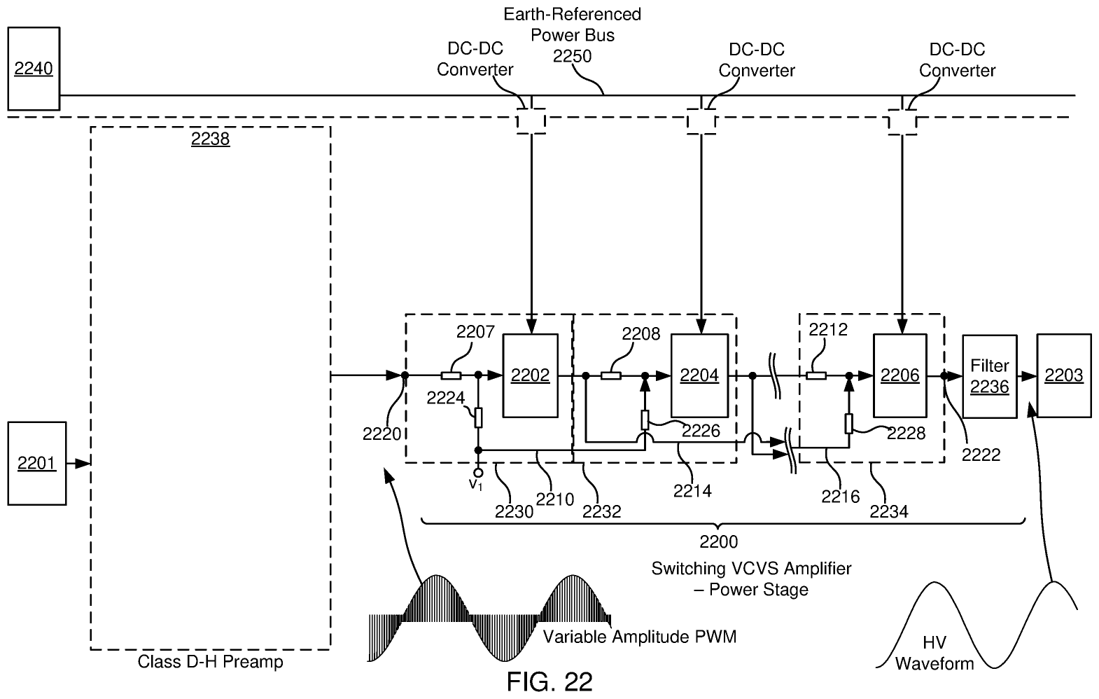

FIG. 9 illustrates an embodiment of a low-voltage amplifier cell such as the ones shown in FIGS. 3, 22, and 23 (e.g., 304, 2204, 2304). In particular, this example shows a low-voltage amplifier cell that could be arranged between other low-voltage amplifier cells, such as the second low-voltage amplifier cell 304 in FIG. 3 or the second low-voltage amplifier cell 2204 in FIG. 22, though the teachings of this figure could easily be applied by one of skill in the art to a first or last (or N^{th}) low-voltage amplifier without undue experimentation. For instance, for the first or last low-voltage amplifier, one of the two feedforward connections 910, 914 would be removed. The low-voltage amplifier 904 has two inputs, a first input 956a and a second input 956b, that at steady state, will be equal in voltage. These voltages are determined by selection of values for the impedance network comprising impedances 908, 926, 940, 942, which can be resistors in one non-limiting embodiment. The impedances can be selected to control a gain of the low-voltage amplifier cell 932, as defined by a ratio of the output 960 over the input 957. Because of the impedance network, the gain of the low-voltage amplifier cell 932 is different than a gain between the first input 956a and the output 960 (or the second input 956b and the output 960).

The low-voltage amplifier 904 can be biased by high and low signals from a DC-DC converter 950 that provides isolation from an earth-referenced power bus 958.

The first input 956a can be coupled to the input 957 as well as the first feedforward connection 910 through impedances 908 and 926, respectively. In other words, the first input 956a can be biased by or coupled to an output of the previous low-voltage amplifier cell and an input of the previous low-voltage amplifier cell via the impedances 908 and 926, respectively. Similarly, the second input 956b can be coupled to the output 960 as well as the first feedforward connection 910 through impedances 942 and 940, respectively. In other words, the second input 956b can be biased by or coupled to the output 960 of the low-voltage amplifier cell 932 as part of feedback of the low-voltage amplifier cell 932 that controls balancing of the differential or balanced inputs of the low-voltage amplifier 904.

The low-voltage amplifier cell 932 also includes two feedforward connections, a first 910 and a second 914. The first feedforward connection 910 couples an input of a previous low-voltage amplifier cell to an input of the low-voltage amplifier 904 through the impedance component 926. The second feedforward connection 914 couples the input 958 of the low-voltage amplifier cell 932 to a next low-voltage amplifier cell and in particular to one of two inputs of that next low-voltage amplifier through a respective impedance component of the next low-voltage amplifier cell.

Although not shown, the low-voltage amplifier cell 932 could include a power gain stage at the output, for instance, comprising a switched pair of MOSFETs or other switches, as is well known to those of skill in the art.

FIG. 6 illustrates an embodiment of a low-voltage amplifier cell such as the ones shown in FIG. 3 (e.g., 304). In particular, this example shows a low-voltage amplifier cell that could be arranged between other low-voltage amplifier cells, such as the second low-voltage amplifier cell 304 in FIG. 3, though the teachings of this figure could easily be applied by one of skill in the art to a first or last (or N^{th}) low-voltage amplifier without undue experimentation. For instance, for the first or last low-voltage amplifier, one of the two feedforward connections 610, 614 would be removed. FIG. 6 shows that the low-voltage amplifier can be embodied by discrete components, such as transistors as shown in this differential pair example. In particular, the inputs 656a and 656b respectively feed a first and second transistor 662, 664. Transistors 662, 664 are biased through resistors 666 668, respectively, by a high signal from a DC-DC converter 650 that provides isolation from an earth-referenced power bus 658. The inputs 656a, 656b control gates of the transistors 662, 664 and thereby control an amount of current drawn through each transistor 662, 664 and provided to a low input of the DC-DC converter 650. This operation is enhanced by a current source 670 that can be embodied by a resistor in an embodiment, or more complex circuitry in other embodiments. The output 660 can be taken from either leg of the low-voltage amplifier since the differential pair produces equivalent current and voltage between the respective transistors 662, 664 and resistors 666, 668. Thus, the circuit is not limited to taking the output 660 from the node between transistor 662 and resistor 666.

Here, one sees the impedance network comprising four distinct impedance components 608, 626, 640, 642 that can be implemented as resistors in one embodiment. The impedances can be selected to control a gain of the low-voltage amplifier cell 632, as defined by a ratio of the output 660 over the input 657. Because of the impedance network, the gain of the low-voltage amplifier cell 632 is different than a gain between input 656a and output 660 (or between input 656b and output 660).

The low-voltage amplifier cell 632 also includes two feedforward connections, a first 610 and a second 614. The first feedforward connection 610 couples an input of a previous low-voltage amplifier cell 632 to a first input 656a of the low-voltage amplifier (i.e., the transistor 662) through the impedance component 662. The second feedforward connection 614 couples the input 657 of the low-voltage amplifier cell 632 to a next low-voltage amplifier cell and in particular to one of the two transistors of that next low-voltage amplifier cell through a respective impedance component thereof.

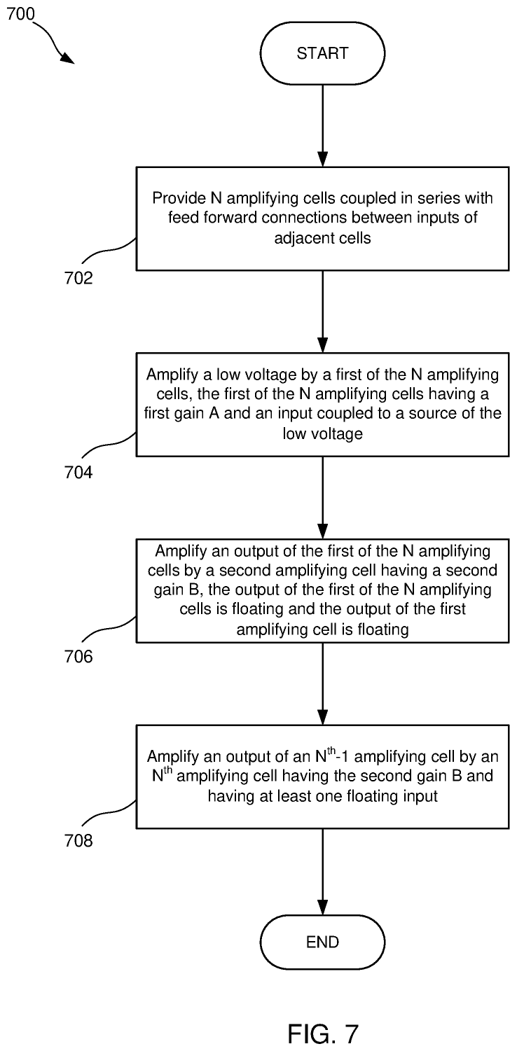

FIG. 7 illustrates a method of amplifying a low voltage to a high voltage. The method 700 includes providing N amplifying cells coupled in series with feed forward connections between inputs of adjacent cells (Block 702). The method 700 further includes amplifying the low voltage by a first of the N amplifying cells, the first of the N amplifying cells having a first gain A and an input coupled to a source of the low voltage and the input coupled to a reference voltage such as ground (Block 704). The method 700 further includes amplifying an output of the first amplifying cell by a second amplifying cell having a second gain B and at least one floating input and wherein the output of the first amplifying cell is floating (Block 706). The method 700 can yet further include amplifying an output of an N^{th}-1 amplifying cell by an N^{th} amplifying cell having the second gain B and having at least one floating input (Block 708). The second gain B can be controlled by the feedforward connections, and more specifically, by an impedance network that includes an impedance component on each feedforward connection. Changing this impedance value on the feedforward connections adjusts the gain B.

In some cases, all amplifying cells can have the same gain, referred to as A (i.e., A=B). In other cases, different amplifying cells may have different gains, for instance the first cell can have a gain B and the remaining cells can have a gain A. The gain A, whether equal to B or not, can equal 2. However, the gain A can be greater than 2 and, in some cases, can be an exponential of 2 (i.e., 2^{C}, where C is a positive integer), such that A can equal 2, 4, 8, 16, etc. In some embodiments, the gain A can equal 2^{C} and be less than a ratio of the output voltage over the input voltage. For instance, where the input voltage is 1V and the output voltage is 500V, C can be any positive integer such that 2^{C}<500/1 (i.e., C is a positive integer less than 9) and hence there could be up to 256 amplifying cells (2⁹). Regardless of the gain of each cell or the number of cells N, the serial topology of the amplifying cells means that an output of each low-voltage amplifier in each low-voltage amplifier cell sees a common current. In some embodiments, no more than 50V drops across, or can be measured across, adjacent amplifying cells or across components within a given amplifying cell.

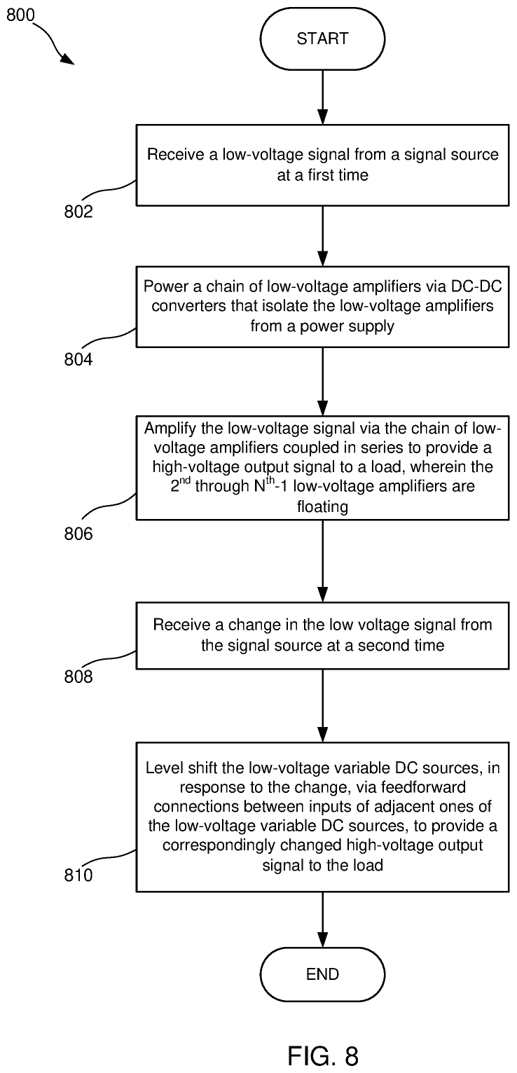

FIG. 8 illustrates a method of amplifying a low voltage to a high voltage. The method 800 includes receiving a low voltage signal from a signal source (e.g., 301 in FIG. 3) at a first time (Block 802). The method 800 further includes powering a chain of low-voltage amplifiers via DC-DC converters that isolate the low-voltage amplifiers from a power supply (Block 804). These low-voltage amplifiers include any number of diverse types of amplifiers such as those shown as 302, 304, and 306 in FIG. 3, or 402, 404, 406 in FIG. 4. An exemplary chain 300 is seen in FIG. 3. The method 800 further includes amplifying the low voltage signal via the chain of low-voltage amplifiers coupled in series to provide a high-voltage output signal to a load (e.g., 303 in FIG. 3), wherein the second through N^{th}-1 low-voltage amplifiers are floating (Block 806). As seen in FIG. 4 for instance, the first low-voltage amplifier 402 has an input at V₁, which may be grounded or held to some non-zero value, but is not floating. In contrast, the second low-voltage amplifier 404 is floating. Further, the last low-voltage amplifiers 406 (or the N^{th} low-voltage amplifiers) would be floating except for being coupled to a ground-referenced circuit such as a load. Thus, the first and last low-voltage amplifiers 402 and 406 are either grounded or held to some non-floating voltage, whereas the low-voltage amplifiers therebetween (i.e., the 2^{nd} through the N^{th}-1) are floating.

Since applications will often be directed to dynamic low-voltage signals, such as pulsed waveforms, stepped waveforms, and arbitrary waveforms, the method 800 can further include receiving a change in the low-voltage signal from the signal source at a second time (Block 808). In other words, the signal source (e.g., 301 in FIG. 3) can provide a variable output and the signal input 420 in FIG. 4 can be a varying voltage. In FIG. 5, voltages are provided at a certain moment in time and thus the example input of 1V may be different at a second time. The method 800 yet further includes level shifting the low-voltage amplifiers, in response to the change, via feedforward connections (e.g., 310, 314, 316 in FIGS. 3 and 410, 414, 416 in FIG. 4) between inputs of adjacent ones of the low-voltage amplifiers, to provide a correspondingly changed high-voltage output signal to the load (Block 810). Said another way, the feedforward connections allow the cascoded high-voltage amplifier to nearly instantly respond at the output 422 to changes at the input 420.

The method 800 is applicable to any of the cascoded high-voltage amplifiers described in this disclosure, including, but not limited to, those shown in FIGS. 3-6 and 9.

### Class D-H Preamplifier and Cascoded Low-Voltage Amplifier Power Stage

Power electronics designers are continuously looking for topologies that can follow higher frequency signals and yet also deliver high power. Class D, or switching amplifiers, typically achieve high speed, but when combined with high power amplification, such as at 1 kV or more, these amplifiers begin to radiate noticeable microwave radiation. The forementioned VCVS power amplifier cells have the ability to operate at high frequencies, yet because of the cell-based topology, no one cell swings between the full high voltage extents. Thus, in theory the VCVS power amplifier can achieve higher rates and higher power without noticeable microwave radiation.

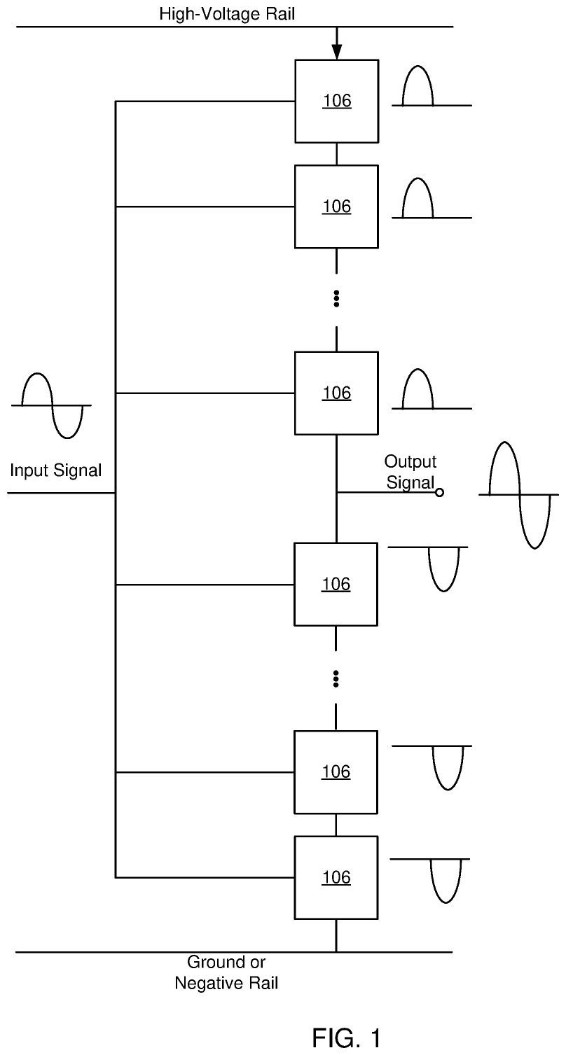

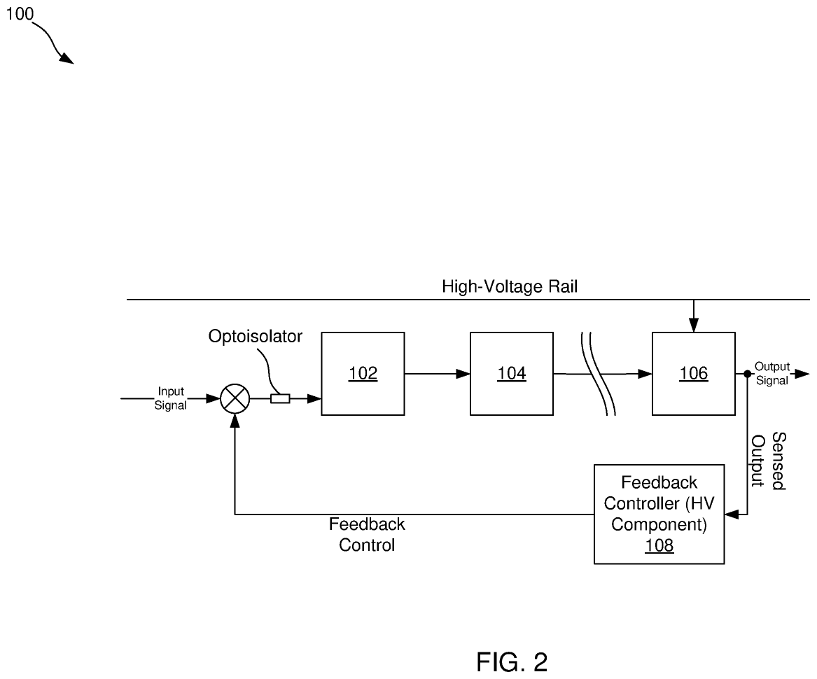

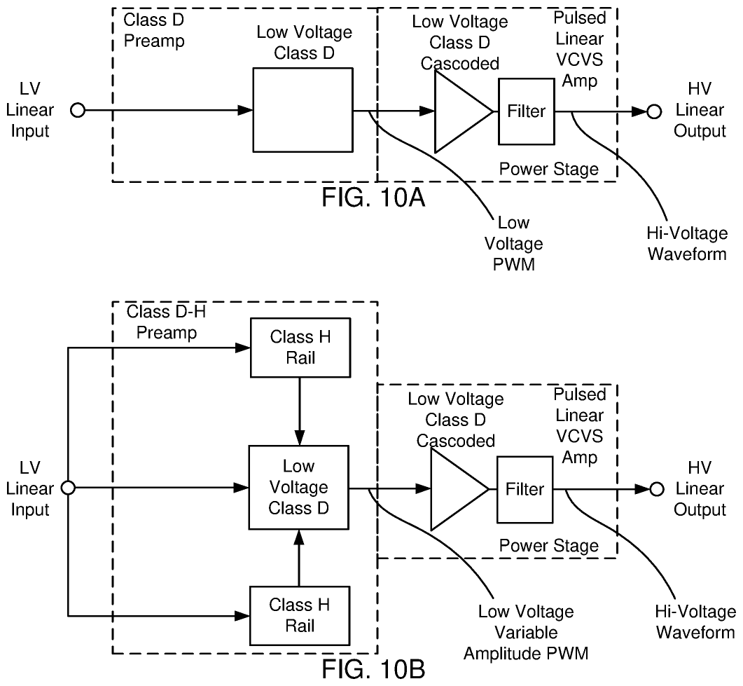

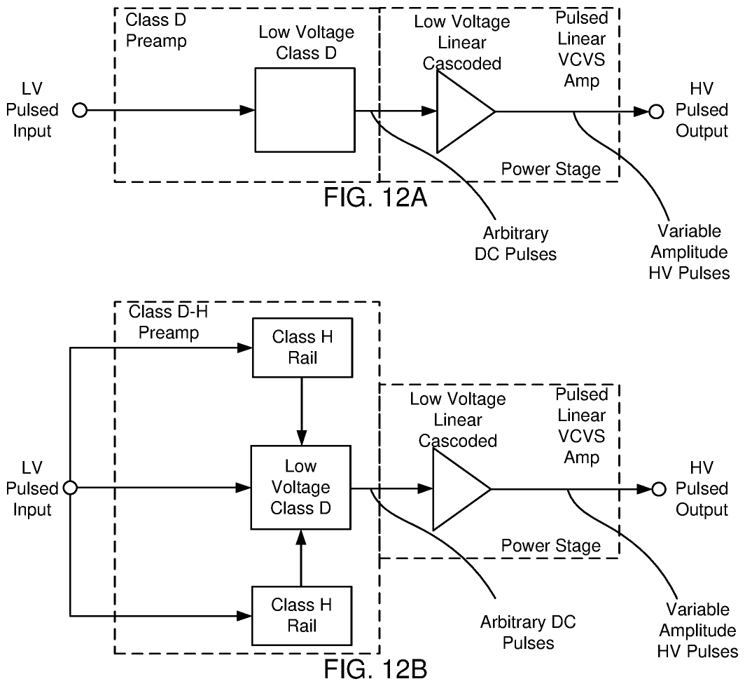

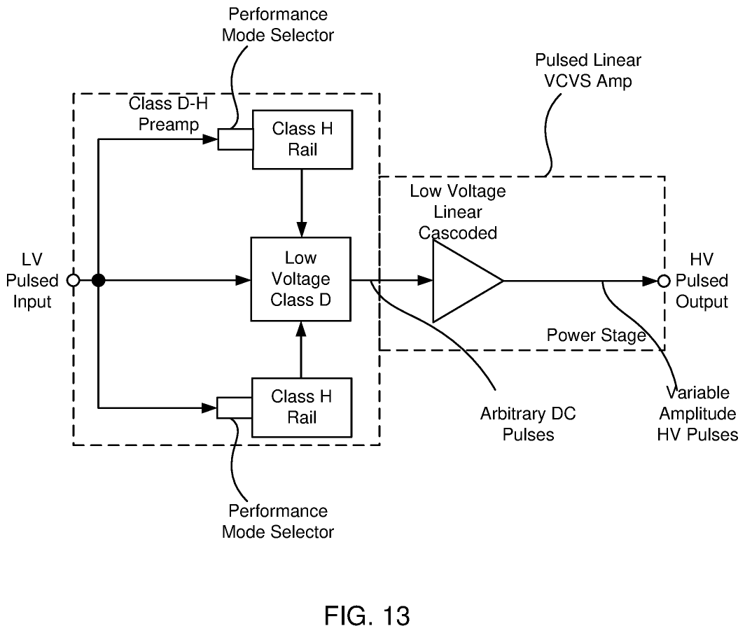

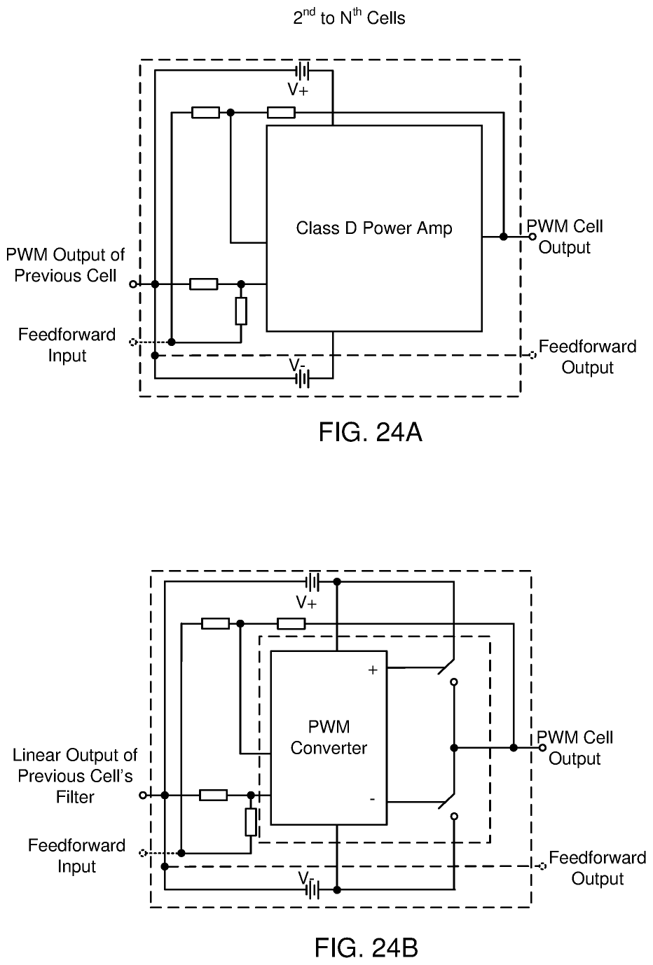

In practice however, the VCVS is a linear device incapable of achieving pure Class D amplifier switching speeds. To better mimic the frequency of a pure switching amplifier, the VCVS can be implemented using high-speed switches such as MOSFETs and can be coupled to a Class D or switching preamplifier as shown in FIG. 10A. In other words, switches capable of sub microsecond switching speeds (e.g., nano and picosecond) are preferred. Generally, this disclosure relates to amplifiers that incorporate a switched preamplifier and a power amplifier operating at nano and picosecond switching speeds. In some aspects, the power amplifier may include a first amplifying cell and a second amplifying cell, with a feedforward connection between them. The first amplifying cell may be coupled between the switched preamplifier and the second amplifying cell, facilitating level shifting between the two or more amplifying cells in the power amplifier. The Class D cascoded high voltage amplifier shown in FIG. 10A can have a topology similar to that seen in FIGS. 3-6 and 9, but with different low-voltage amplifiers 302, 304, 306, 904, where N series-coupled low voltage cells are used to amplify a low voltage input signal, but here from a Class D preamplifier and where N is two or more. Details of the low-voltage amplifiers will be discussed relative to FIGS. 24-25 and 27-28. Low-voltage linear amplifiers can be used where the input signal is pulsed (e.g., see FIGS. 12 and 13). The feedforward connections replace traditional feedback and voltage control mechanisms in power amplifiers, sub-systems that greatly increase a product's cost of materials when high voltages are involved. For instance, even a mere voltage divider comprising two resistors, when designed for high voltage applications (e.g., over 500 V), involves much costlier and less-common resistors. The VCVS with feedforward connections achieve high voltage amplification while using low voltage components, thus greatly enhancing the value proposition of products using this amplifier. More specifically, traditional amplifiers, even using a cell-based approach, are limited by the high voltage components they are using (e.g., expensive and hard to source resistors and switches). Thus, a traditional amplifier's output is limited by the components therein. The cell-based approach used herein, along with the use of low-voltage amplifiers and corresponding low-voltage components, allows a nearly infinite number of cells to be stacked to achieve any output voltage. In other words, low voltage components can be used whether the output voltage is 500V or 50,000V, thereby providing a scalability not seen in the art. This is largely possible due to the use of feedforward connections to control level shifting and replace traditional opto-isolators and the allowance of all but the first and last cells to float. Details of the VCVS that makes this possible have been describe relative to FIGS. 1-9, and now FIGS. 10-35 will discuss high speed applications and improved efficiency.

In order for the power stage to keep pace with the Class D (or Class D-H) preamplifier, the low-voltage amplifier in each cell includes one or more switches having a switching speed substantially the same or greater to that of the switches in the preamplifier. For instance, MOSFETs can be used in the power stage, fast linear switches biased to a switching regime, or fast FJETs with some loss of stability resulting as a compromise to their slightly slower speed. Typically, devices having nano and picosecond switching speeds are effective.

The preamplifier can be a Class D or switching amplifier that converts a low-voltage linear input signal to a PWM signal that is passed to the power stage. A filter, such as an RLC filter, at the output of the power stage, or distributed within the power stage amplifier cells, can smooth the amplified PWM signal to form a linear output. Alternatively, where the amplifier operates on pulsed or other nonlinear signals, the preamplifier can again be a Class D or switching amplifier, but merely amplifies the low voltage pulsed input signal (no PWM conversion is needed), as shown in FIG. 12A.

In some embodiments, additional linearity of the amplifier output signal can be achieved by adding variable rails to the preamplifier as shown in FIGS. 10B and 12B. With these variable rails, the Class D pulsed output can be given a more linear output via the variable rails resulting in an output signal that can be characterized as variable PWM, and the preamplifier can be called a Class D-H or switching amplifier with variable rails.

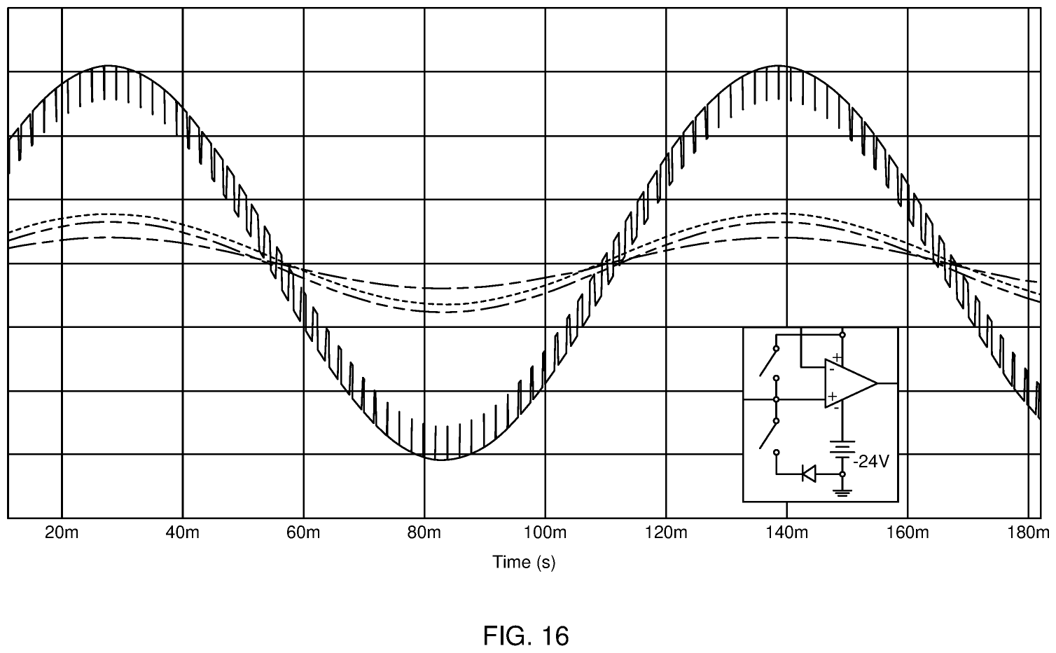

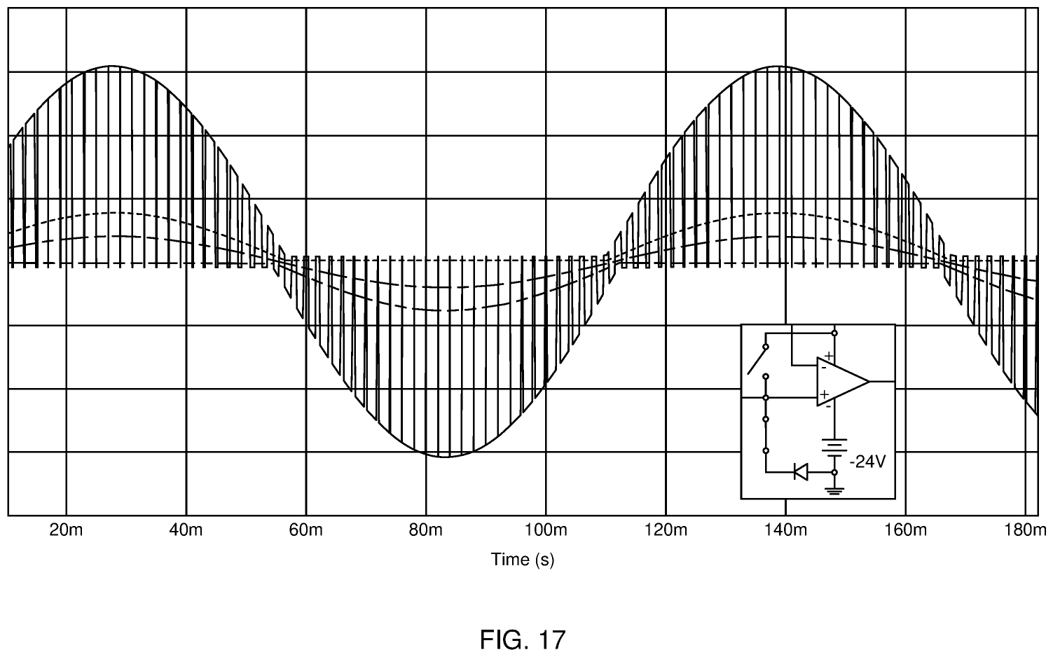

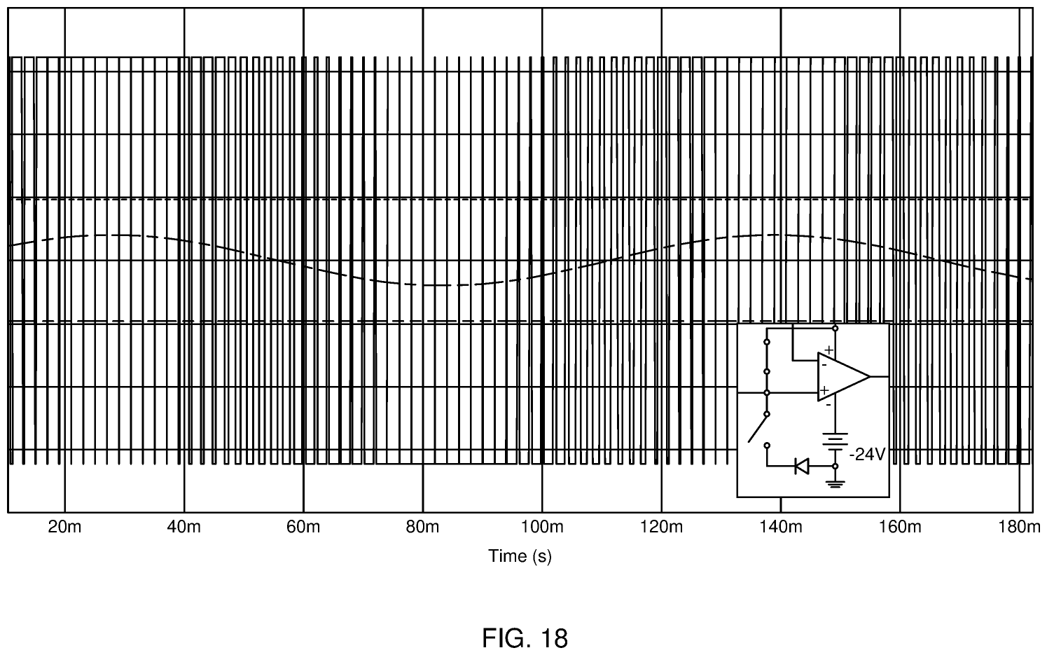

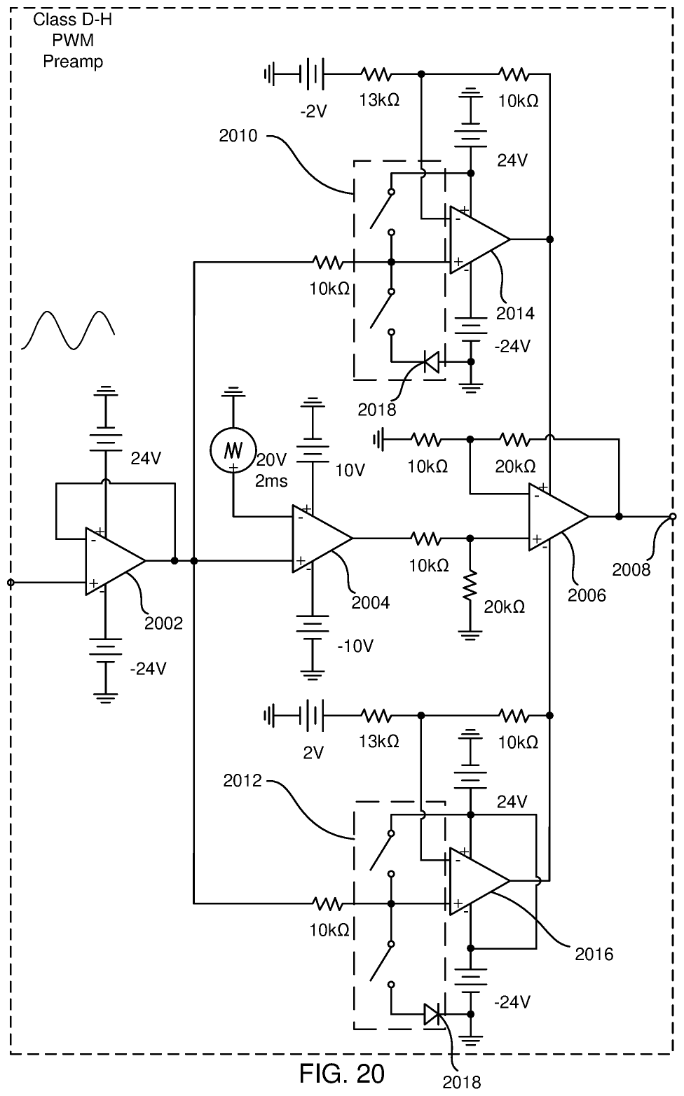

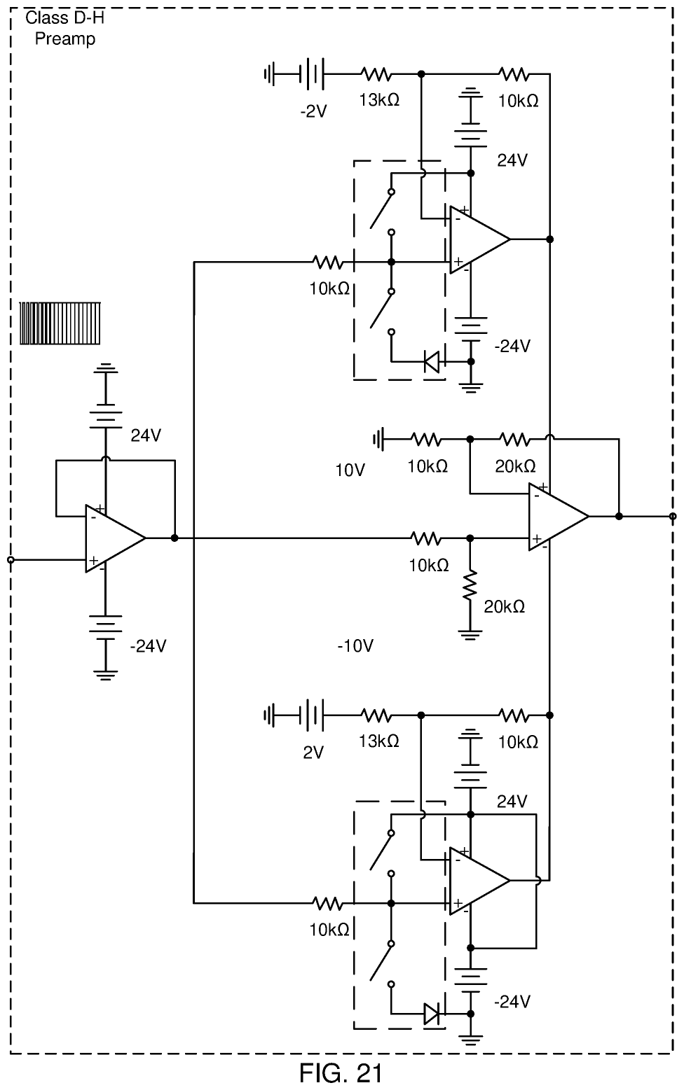

The preamplifier also has the ability to swing between pure H and pure D modes of operation as well as to operate in a blended state between these two extremes. For instance, FIG. 16 illustrates a timing chart for the preamplifier that blending linear and switching signals. In particular, the rails are tracking the input signal linearly while the class D amplifier is also tracking the input signal via conversion to a PWM. As the rails of the class D amplifier swing with the changes in the input signal, the result is a PWM signal following movement of the linearly-changing rails. It should be noted that while traditional Class H amplifiers use stepped changes between rail values, in this disclosure, the Class H amplifier uses infinitely variable rails. This can be accomplished, for instance, by using op amps to drive the rails of the Class D amplifier, as seen in FIGS. 20 and 21, but any variable source could drive the Class D rails, as seen in FIG. 36. FIG. 17 illustrates a timing chart for the preamplifier that is blended closer to 50/50 between the linear and switching regimes. One can also see that where a rail is not needed during a cycle, that rail can be clamped to 0 V. FIG. 18 is a timing chart for the preamplifier in a full switching regime, with the variable rails playing no role in the preamplifier output. In some cases, the blending of D and H modes may be adjusted based on the characteristics of the input signal or other operating conditions of the amplifier. For instance, when the input signal is at a low frequency, the amplifier may operate primarily in the D mode to take advantage of the high efficiency of switching amplifiers. On the other hand, when the input signal is at a high frequency, the preamplifier may operate primarily in the H mode to reduce distortion and improve linearity. This dynamic adjustment of the blending of D and H modes may allow for real-time control over the preamplification process, potentially improving the performance of the preamplifier in response to changes in the input signal or operating conditions.

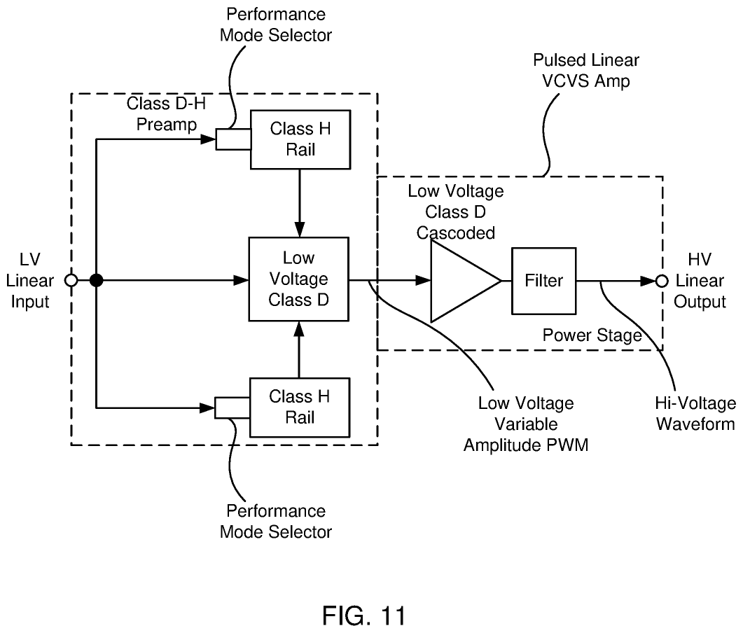

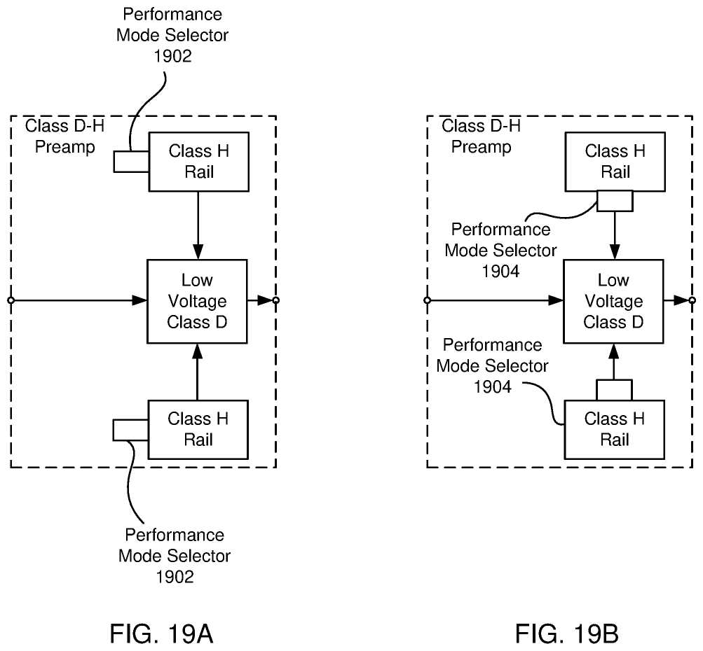

The performance mode selectors seen in FIGS. 11 and 13 can control the blending between D and H modes of the preamplifier, and one embodiment of a performance mode selector is seen in the lower right of each of FIGS. 16-18. These inset topologies show a lower of two performance mode selectors or a one of the two that is coupled to a negative power source. In this embodiment, when both switches are open, the D-H preamplifier operates in a blend of D and H modes where the blending is selected based on impedance components of the performance mode selector (not shown). FIGS. 19A and 19B show that the location of the performance mode selectors can be varied without departing from the spirit and scope of the disclosure. For instance, the performance mode selectors can be on inputs of the Class H or variable rails (FIG. 19A), or on outputs thereof (FIG. 19B). When a one of the two switches coupled to ground via a diode is closed, the D-H blending favors the linear and the diode dictates that the rails are clamped to 0 V during the portion of each cycle where a one of the two rails is not needed. When a switch shorting the non-inverting input of the op amp and the high rail of the op amp is closed, the blending is pushed entirely to the switched mode or Class D. In other words, the variable rails are effectively removed from the preamplifier.

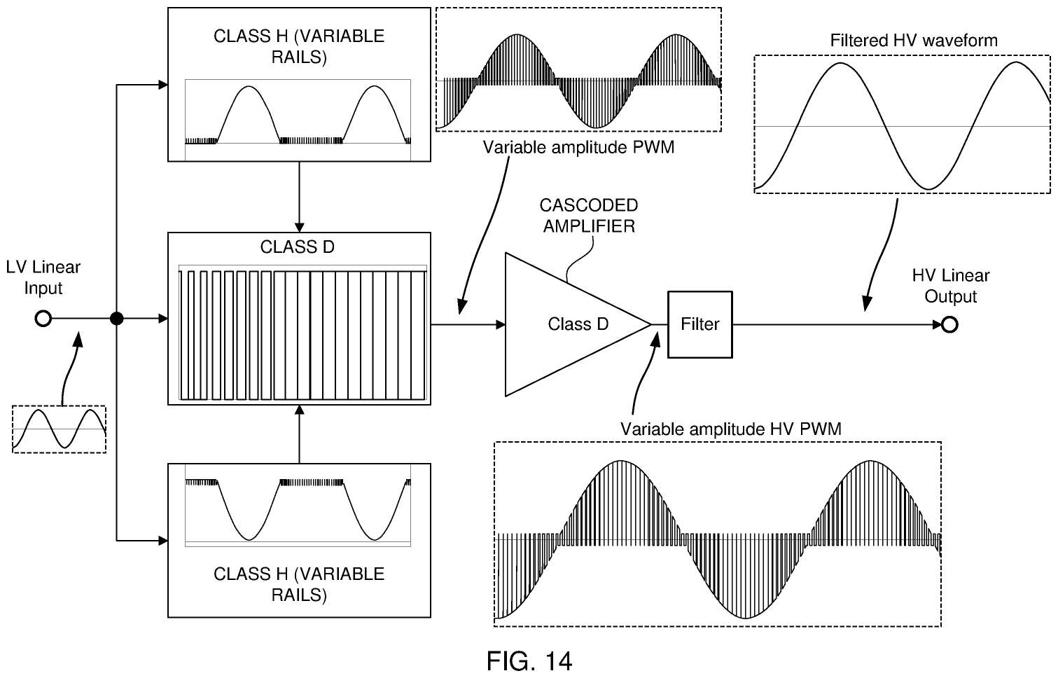

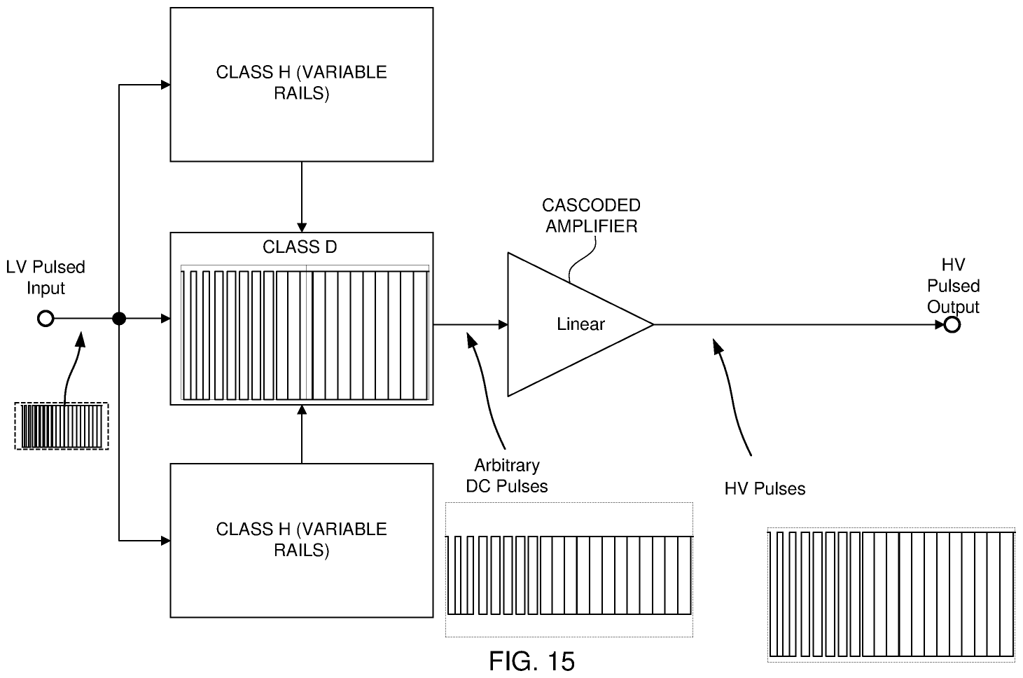

FIGS. 14 and 15 show high level diagrams of the amplifier for linear and pulsed signals. In FIG. 14 one can see a low voltage linear input, such as a sine wave. The preamplifier converts this linear signal to a PWM signal via a triangle wave carrier signal, while the Class H or variable rails cause the PWM output to have a variable amplitude (depending on the performance mode selection). Thus, the preamplifier output is a variable amplitude PWM signal where some blending of the H and D modes is selected (if a pure H mode is selected, then the preamplifier output will be purely linear and if a pure D mode is selected, then the preamplifier output will be purely PWM). The Class H rails and the first Class D amplifier form a Class D-H preamplifier configured to operate in pure D, pure H, or a blend of D and H regimes. The variable amplitude PWM signal from the Class D-H preamplifier is provided to the power stage and the cascoded Class D amplifier having two or more low-voltage amplifier cells that are either filtered once at the output or between each cell, to produce a linear and high voltage output. The series of two or more coupled low-voltage amplifiers amplifies the linear signal to a high voltage linear output without high voltage swings within any of the cells within the power stage. In other words, the variable amplitude PWM signal is passed through the power stage without signal modification (other than gain). This illustration shows PWM signals that are clamped at 0V on off cycles, but otherwise show a blending of D and H modes. However, this shows just one of numerous performance modes that the Class H variable rails can be set to. For instance, in other embodiments, any of FIGS. 16-18 can represent the PWM waveform provided by the Class H rails and Class D preamplifier shown. Further, while a single filter is shown at the output of the Cascoded amplifier, in other embodiments, the filter may be distributed throughout the cascoded amplifier, and more specifically there can be a filter after the Class D-H preamplifier and after each cell within the cascoded amplifier.

For a low voltage pulsed input (FIG. 15), the Class D portion of the Class D-H preamplifier applies gain, but no PWM conversion or triangle wave carrier is used. The Class H or variable rails again provide a selective level of linearity to the preamplification and the Class D-H preamplifier provides a PWM (pulsed) output to the power stage (the cascoded amplifier comprising linear cells). The Class D-H amplifier may offer the high efficiency of Class D amplifiers and the flexible control over the supply voltage of Class H amplifiers. The Class D-H amplifier can also be referred to as a blended D-H amplifier. As with the linear signal variant of FIG. 14, the cascoded amplifier passes the pulsed signal and applies gain without other modification to the signal. However, while the linear variant of FIG. 14 uses Class D or switching low-voltage amplifier cells, the pulsed variant of FIG. 15 uses linear low-voltage amplifier cells in the cascoded amplifier. This hybrid approach of a Class D or Class D-H preamplifier followed by a high speed linear power stage allows the amplifier to follow rise and fall slopes of each pulse, rather than just mimicking the duty cycle and phase of pulses. Along these lines, the Class D-H preamplifier followed by a series of linear low-voltage cells with feedforward connections can be referred to as a “hybrid” switching-linear amplifier. The two or more series coupled low-voltage amplifiers, the cascoded amplifier, amplify the pulsed signal to a high voltage pulsed output without high voltage swings within any of the cells within the power stage.

FIG. 20 presents details of an embodiment of a D-H preamplifier operating on linear signals and providing a PWM signal to the power stage. A low voltage linear input signal first meets an optional buffer 2002, such as an op amp, and the buffered linear signal is passed to a comparator 2004 receiving a triangle wave reference signal at the inverting input. The comparator 2004 produces a PWM signal as a digital representation of the linear input signal. However, any PWM converter could be used in place of the triangle wave comparator 2004. This PWM signal is passed to a class D or switching amplifier 2006, which applies a gain to the PWM signal and provides the amplified PWM signal to the output 2008.

The Class D or switching amplifier 2006 can have fixed rails in some embodiments, but as shown has variable rails and thus operates as a Class D-H amplifier or a switching amplifier with variable rails. Performance mode selectors 2010 and 2012 are coupled to op amps 2014 and 2016 receiving the buffered low voltage linear signal at their non-inverting inputs. Their inverting inputs receive a feedback voltage as is typical for op amp topologies. However, the positive and negative rails for each op amp may be selectively coupled into the non-inverting input depending on a desired performance mode (as seen and described in FIGS. 16-18). For instance, with both switches of both performance mode selectors 2010 and 2012 open, the op amps 2014 and 2016 attempt to track the amplified low-voltage linear input signal and therefore the rails of the Class D amplifier 2006 linearly track the signal to be amplified (the linear signal before being converted to a PWM) with infinite output values. Thus, with both switches open, the performance mode selectors 2010 and 2012 effectively push the preamplifier as far toward pure linear or H mode as is possible. The result is a variable PWM highly blended toward the linear, such as that illustrated in FIG. 16.

With one of the two switches closed creating a short to the diode or lower rail of the op amps 2014 and 2016, the non-inverting inputs and thus the rails of the amplifier 2006 track the amplified linear signal, but due to the diodes 2018 are clamped at 0V during negative half cycles. The result is a strong blending of D and H modes such that the preamplifier output is a variable PWM (See FIG. 17), but with a bottom of the PWM pulled to 0V. These first two performance modes represent one extreme—where the linear dominates.

On the other extreme, Class D dominates or is even the only signal provided by the Class D-H preamplifier (see FIG. 18). In this mode, the class D-H preamplifier can be set to a purely D or switching regime by closing the upper of the switches in both performance mode selectors 2010 and 2012, such that the non-inverting inputs of the op amps see their own high voltage rails, and thereby effectively pass the high voltage rail, which in this example is 24 V, without any passing of the input signal information. In other words, since a fixed rail is passed to the high and low rail inputs of the Class D amplifier 2006, the preamplifier effectively operates as a switching amplifier with fixed rails, as seen in FIG. 18, or a pure Class D amplifier.

As seen, the performance mode selectors are configured to select a blended state of D and H modes for the preamplifier that can range from fully switching or Class D to nearly fully linear or Class H and including blended state therebetween. Blending can be controlled by selection of resistor and capacitor values during manufacturing. However, it can also be selected by adjusting the switches in the performance mode selectors 2010 and 2012 during operation. For instance, adjusting a duty cycle of these switches, or the linear output if linear switches are used, will adjust a blending between D and H modes. Additionally, while the performance mode selectors 2010 and 2012 can control blending from D to H modes and anywhere in between, closing the lower of the two switches in the performance mode selectors 2010 and 2012 enables clamping the lower end of each PWM pulse to 0V as shown in FIG. 17. Thus, any point on the spectrum between D and H modes can be selected for both clamped and non-clamped outputs.

It should be appreciated that FIG. 20 includes various implementation details not necessary for an understanding of the D-H style preamplifier, such as specific resistance and power supply voltages. Other topologies and component values can also be implemented to achieve selective D, H, and blended D-H regimes for linear input signals. For instance, the input buffer 2002 is optional and may not be used in other embodiments.

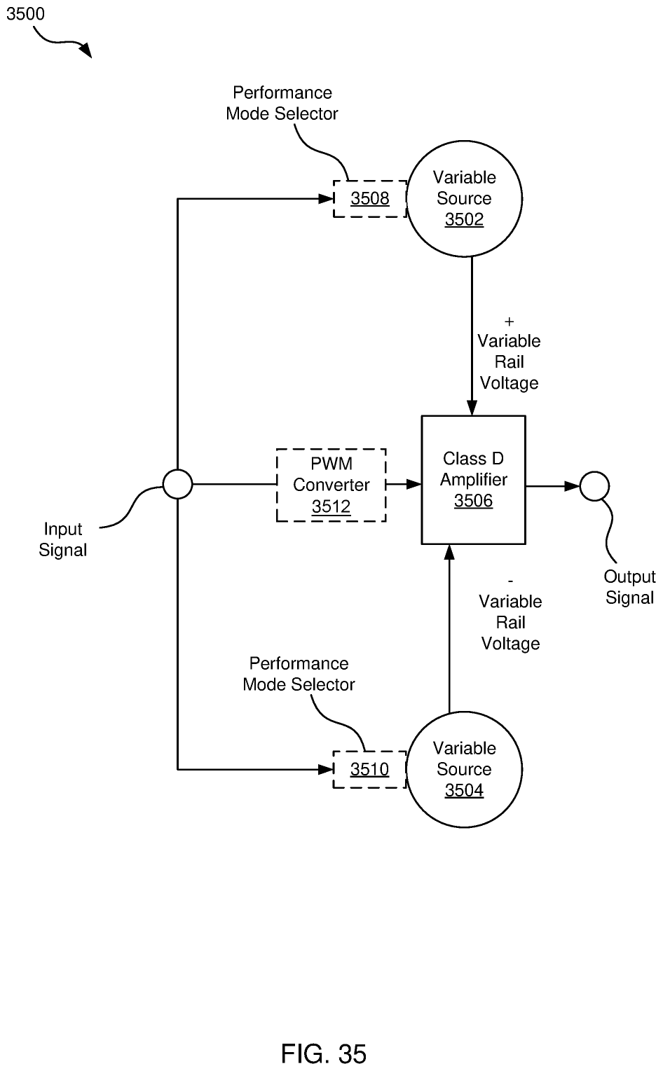

It should be noted that while traditional Class H amplifiers use stepped changes between rail values, in this disclosure, the Class H amplifier uses infinitely variable rails. This can be accomplished, for instance, by using op amps to drive the rails of the Class D amplifier, as seen in FIGS. 20 and 21, but also by any variable source to drive the Class D rails, as seen in FIG. 35.

Similar to FIG. 20, FIG. 21 presents details of an embodiment of a Class D-H preamplifier, but operating on pulsed signals and again providing a PWM signal to the power stage. Most aspects are taken from FIG. 20 and for the sake of brevity are not described again. A difference however, is the lack of the triangle wave comparator, since in this topology, pulses can be passed through the preamplifier without conversion to a PWM. However, the variable rails and performance mode selectors operate as seen and described in FIG. 20.

FIG. 22 illustrates a generalized embodiment of an amplifier that converts a low voltage linear input signal to a high-voltage linear output signal using a Class D-H preamplifier feeding a cascoded high-voltage amplifier having N series-coupled low-voltage amplifiers (the power stage also being referred to as a voltage-controlled voltage source amplifier (VCVS)). N is a total number of low-voltage amplifier cells in the cascoded high-voltage amplifier 2200. The Class D-H preamplifier 2238 can be implemented as described relative to FIGS. 10A, 10B, 11, and 20, and generally operates to convert a low-voltage linear input signal from the signal source 2201 to a variable amplitude low-voltage PWM signal provided to the input 2220 of the cascoded high-voltage amplifier 2200. Furthermore, the Class D-H preamplifier 2238 can operate as a Class D, Class H, or a blended amplifier depending on circumstances and settings of the performance mode selectors. Further, the variable rails are infinitely variable, unlike traditional Class H amplifiers. The PWM output is then amplified by the cascoded high-voltage amplifier 2200 and filtered to produce a linear high voltage output that is provided to a load 2203. The filter 2236 can convert the PWM to a linear signal, or the filter 2236 can be removed and instead a filter can be arranged at the output of each cell 2230, 2232, 2234 (not shown). In this embodiment, each cell 2230, 2232, 2234 generates a PWM while applying gain, the respective filter linearizes the PWM, and the next cell generates a new PWM while applying gain, until the final filter provides a linear high-voltage output to the load 2203.

The low-voltage amplifiers 2202, 2204, 2206, other than the first and last or N^{th}, are floating. Each low-voltage amplifier 2202, 2204, 2206 is also powered or biased by an earth-referenced power supply. For instance, in FIG. 22, a power supply 2240 provides an earth-referenced power bus 2250 with voltage such as 15V, where this earth-referenced power bus 2250 is isolated from the cascoded high-voltage amplifier 2200 via an isolation boundary. In some embodiments, the isolation boundary may be embodied in a transformer, for instance as part of DC-DC converters or regulators, though other forms of isolation can also be implemented. Although FIG. 22 illustrates a rail-style power supply, in other embodiments, each low-voltage amplifying cell 2230, 2232, and 2234 can have its own independent isolated power supply or power regulator. The floating low-voltage amplifiers and the earth-referenced power supply that is isolated from the low-voltage amplifiers 2202, 2204, 2206, along with a feedforward connection 2210, 2214, 2216 between inputs of adjacent low-voltage amplifiers 2202, 2204, 2206, allows a change in the input signal to the cascoded high-voltage amplifier 2200 to level shift the entire chain of low-voltage amplifiers 2202, 2204, 2206. In other words, a change at the preamplifier output propagates through the entire cascoded high-voltage amplifier 2200 with little if any delay or latency, allowing the cascoded high-voltage amplifier 2200 to track high frequency signals. At the same time, the floating nature of all but the first and last (or N^{th}) low-voltage amplifiers means that voltage differences between low-voltage amplifiers can be limited to “low voltage” such as, less than or equal to 50V, or only using components tailored to or rated to up to 50V. This allows most if not all of the cascoded high-voltage amplifier 2200 to be constructed using common and inexpensive off-the-shelf low voltage components, yet achieve high voltage amplification (e.g., 1V in and 60V out, or 1V in and 120V out, or 1V in and 1 KV out, etc.).

In some embodiments, each low-voltage amplifier 2202, 2204, 2206 can have at least one input that is biased or controlled by an impedance network (having at least two impedance components in FIG. 22). For instance, each impedance network can include four resistors. The combination of a low-voltage amplifier, the impedance network, and a feedforward connection can form a low-voltage amplifier cell, of which a first 2230, a second 2232, and an N^{th} 2234 (or last) are shown in FIG. 22-though some number of optional additional cells are not shown for the sake of simplicity. At a minimum, a cascoded high-voltage amplifier 2200 can include two cells and thus two amplifiers, though at least three are shown in FIG. 22. The number of cells and low-voltage amplifiers is not limiting, though cost, size, and complexity may steer designers toward a minimum number, which the inventor believes is achieved when each cell has a gain of 2.

Like the low-voltage amplifiers other than the first and N^{th} or last, the low-voltage amplifier cells, except the first and N^{th} or last, are floating. This, along with being isolated from the power supply 2240, and the feedforward connections 2210, 2214, 2216, means that the cascoded high-voltage amplifier 2200 can respond to changes in input signal using low voltage cells. In other words, the impedance networks and feedforward connections can also use components tailored for low voltage operation or rated up to 50V, which are often off-the-shelf and low-cost components.

Additionally, it should be noted that since the voltage drop across any one low-voltage amplifier 2202, 2204, 2206 or low-voltage amplifier cell 2230, 2232, 2234 is low voltage (i.e., less than or equal to 50V), power dissipation is relatively low and evenly distributed across the cascoded high-voltage amplifier 2200. In the case where the chain of cells gets too long in a certain direction, for instance, from a packaging standpoint, the chain can follow a u-shaped or s-shaped path to maintain a compact package. Further, circuit boards can be stacked in order to add even more cells while still maintaining a relatively compact overall high-voltage amplifier package.

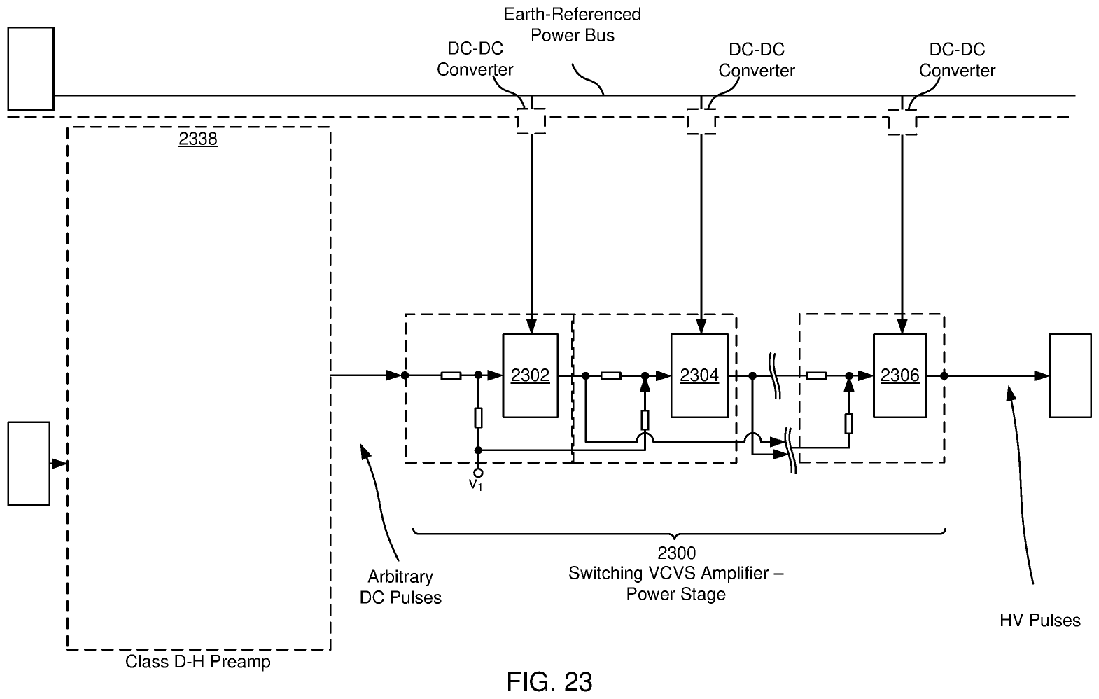

While the low-voltage linear amplifiers so far discussed achieve high output with relatively inexpensive and less complex devices than prior art high-voltage amplifiers, they still operate hotter than Class D or switching amplifiers. Accordingly, embodiments of the aforementioned VCVS power amplifier cells (or low-voltage amplifiers) are now described that have class D or switching topologies, at least for pulsed signals. This allows smaller, cooler, and/or faster switching and in a smaller package. For pulsed signals, low-voltage linear amplifiers will be described. The cascoded high-voltage amplifier 2200 can include a voltage input 2220 that may be a part of the first cell 2230 or arranged between the preamplifier 2238 and the cascoded high-voltage amplifier 2200. The voltage input 2220 is coupled to an output of the preamplifier 2238 and is configured to receive an amplified version of a low-voltage signal from the signal source 2201. The low-voltage input signal can be linear at the preamplifier 2238 input and PWM at the preamplifier 2238 output. DC, AC, and arbitrary waveforms can be implemented. Pulsed waveforms are best addressed by the topology of FIG. 23.

A voltage output 2222 may or may not be a part of the last or N^{th} amplifier cell 2234, and the voltage output 2222 can be configured for coupling to a load 2203 via a filter 2236, though the filter 2236 may also be distributed through the cascoded high-voltage amplifier 2200 after each cell 2230, 2232, 2234. The load 2203 can take a variety of forms such as, but not limited to, a speaker's voice coil, a digital circuit on a circuit board, a plasma in a plasma processing chamber, or the rotor or stator of an electrical motor. In other words, the cascoded high-voltage amplifier 2200 with Class D-H preamplifier 2238 can be coupled between a signal source 2201, and a load 2203. Electrical connections well known to those of skill in the art can be made between (1) the signal source 2201 and the preamplifier 2238, and (2) between the cascoded high-voltage amplifier 2200 and the load 2203.

The low-voltage amplifiers 2202, 2204, 2206, can be, but are not limited to, a variable DC source, class D amplifier, variable power source or supply, voltage-controlled voltage source, DC-DC converter, signal booster, op amp, differential pair, symmetrical circuit, etc. In some cases, the low-voltage amplifiers 2202, 2204, 2206 can be voltage sources, though current and power sources can also be implemented. It should also be understood that the low-voltage amplifiers 2202, 2204, 2206 are not limited in response time, and can therefore provide low-latency signal tracking of any linear signal including, but not limited to, AC and arbitrary waveforms. In some cases, digital amplifiers can be used for the low-voltage amplifiers 2202, 2204, 2206 where higher frequency input signals are used (e.g., greater than 5 MHz). In some cases, the low-voltage amplifiers 2202, 2204, 2206 can be replaced with high-voltage amplifiers, such as those using components rated to greater than 50V. These situations may be seen where an especially large output voltage is desired.

In some cases, the first low-voltage amplifier 2202 is different than the remaining low-voltage amplifiers 2204, 2206 or may not even be an amplifier. For instance, a buffer or other device having a gain of 1 could be used in place of the low-voltage amplifier 2202. Said another way, the first amplifying cell 2230 can have a gain of 1 and subsequent amplifying cells have a gain greater than 1. Similarly, the low-voltage amplifiers 2202, 2204, 2206 may have the same gain, while in other situations different gains may be used. In one embodiment, the second through last or N^{th} low-voltage amplifier 2204, 2206 have a gain of 2, while in another embodiment, all of the low-voltage amplifiers 2202, 2204, 2206 have a gain of 2.

Each low-voltage amplifier cell 2230, 2232, 2234 can have an input and an output. The first low-voltage amplifier cell 2230 can be configured to amplify the preamplifier 2238 output with a first gain to provide an amplified version of the input voltage at the first output of the first low-voltage amplifier 2202, which can be provided to an input of the second low-voltage amplifier cell 2232. The second low-voltage amplifier cell 2232 can include a second low-voltage amplifier 2204 configured to amplify the first output by a second gain. The first low-voltage amplifier cell 2230 can include a first feedforward connection 2210 between the first input of the first low-voltage amplifier 2202 and a first input of the second low-voltage amplifier 2204. The first input of the second low-voltage amplifier 2204 can be formed by a sum of the output of the first low-voltage amplifier 2202 and the first feedforward connection 2210. For instance, this summing can be performed by a voltage divider comprising impedance components 2208 and 2226 (e.g., resistors). In an embodiment, the output of the first low-voltage amplifier 2202 can be coupled to the first input of the second low-voltage amplifier 2204, and the input of the first low-voltage amplifier 2202 can be coupled to the first input of the second low-voltage amplifier 2204. This coupling can be made via a voltage divider such that the second low-voltage amplifier 2204 is at a voltage less than the output of the first low-voltage amplifier 2202 but greater than the input of the first low-voltage amplifier 2202. Said another way, the output of the first low-voltage amplifier 2202 is coupled to the input of the second low-voltage amplifier 2204 via an impedance component 2208, such that voltage actually drops between an output of one low-voltage amplifier and an input of a next low-voltage amplifier. Thus, while the overall cascoded high-voltage amplifier 2200 amplifies the input signal at input voltage 2220, voltage actually drops between low-voltage amplifiers.

As noted, the first low-voltage amplifier 2202 or low-voltage amplifier cell 2230 can be referenced to ground. FIG. 22 shows the first feedforward connection 2210 being optionally held at voltage V₁, which in some cases is ground. However, more importantly, the first feedforward connection 2210 can be held to whatever voltage, V₁ the signal source 2201 is referenced to, which may be ground, but may also be some non-zero voltage. The final or N^{th} low-voltage amplifier cell 2234 is referenced to the load 2203.

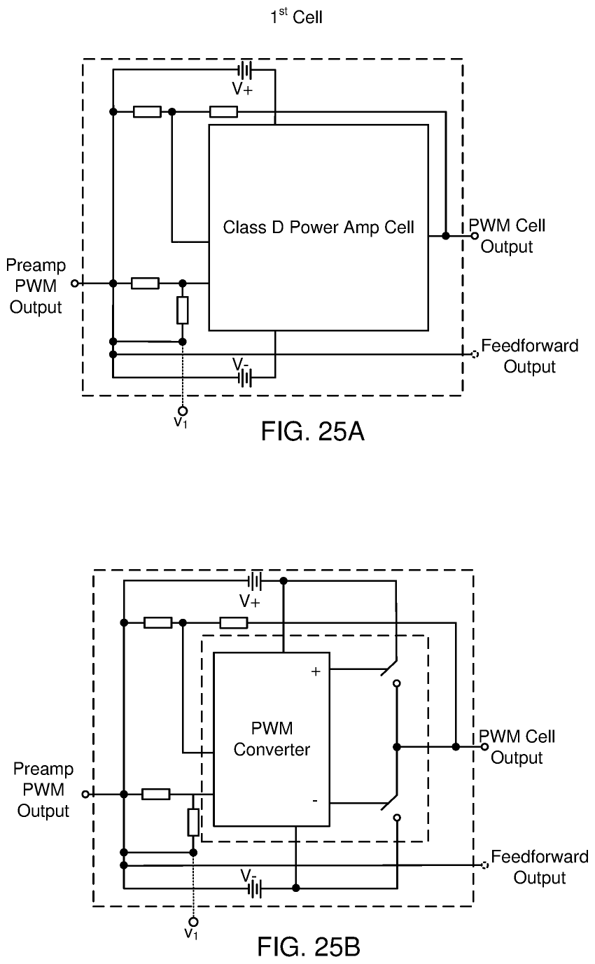

Each feedforward connection 2210, 2214, 2216 may pass through an impedance component (e.g., 2226, 2228) in route to an input of a next low-voltage amplifier. Similarly, each output of a low-voltage amplifier 2202, 2204, 2206 or low-voltage amplifier cell 2230, 2232, 2234 may pass through an impedance component (e.g., 2208, 2212) in route to the input of the next low-voltage amplifier. Said another way, each low-voltage amplifier except the N^{th} or last one, can be coupled to a next or next adjacent low-voltage amplifier via an impedance component. The impedance components can include resistors or other resistive devices, though reactive components and components having both resistive and inductive components could also be implemented. In other terms, devices seeing a voltage drop can be implemented as the impedance components so long as they are selected to achieve a desired voltage drop from low-voltage amplifier output to low-voltage amplifier input that achieves a desired gain across a respective low-voltage amplifier cell (i.e., from one low-voltage amplifier output to an output of a next low-voltage amplifier). The impedance components 2207, 2224, 2208, 2226, 2212, 2228 can be part of impedance component networks, one impedance component network for each low-voltage amplifier cell 2230, 2232, 2234 or each low-voltage amplifier 2202, 2204, 2206. In FIG. 22 the impedance component network comprises two impedance components, though more could be implemented as shown in FIGS. 24A, 24B, 25A, and 25B, where there are four impedance components per impedance component network.

As noted earlier, the low-voltage amplifier cells 2232, 2234, except the first low-voltage amplifier cell 2230 are each provided with power isolated from a grounded source of the power (e.g., power supply 2240). In other words, all but a first low-voltage amplifier cell 2230 and a final or N^{th} amplifier cell 2234, in the chain is floating and receives power from DC-DC converters that are isolated, or include isolation from, the power supply 2240 (or their power supply where each cell has a separate power supply). Packaging for the cascoded high-voltage amplifier 2200 may also support the isolation boundary, for instance a PCB without any conductive traces that cross the isolation boundary, or a PCB with elongated slits formed therein in a zigzagging pattern may reduce a cross section of the PCT spanning the isolation boundary thereby increasing dielectric resistance at the isolation boundary. In FIG. 22 one sees that each low-voltage amplifier cell 2230, 2232, 2234 receives power from an earth-referenced power bus 2250, and is also isolated from the earth-referenced power bus 2250 and the source of power to the earth-referenced power bus 2250 (e.g., the power supply 2240). Although not explicitly illustrated, these isolated DC-DC regulators or converters can be regulated such that a specific voltage is provided to each of the low-voltage amplifiers 2202, 2204, 2206. Interestingly, the earth-referenced power bus 2250 does not need to be high voltage (e.g., greater than 50V). For instance, if the input signal is 10V and the gain of each low-voltage amplifier is 2 or 20V, then a 25V earth-referenced power bus 2250 could be used, and with enough low-voltage amplifier cells, the output could be many hundreds or even thousands of volts. For instance, 50 low-voltage amplifier cells would enable a 1000V output despite the earth-referenced power bus 2250 being a mere 25V. As those of skill in the art will appreciate, the ability to achieve high voltage outputs with only low-voltage rails/buses and power supplies is a huge cost, size, and complexity advantage over the prior art.

Further, feedforward connections 2210, 2214, 2216 between adjacent low-voltage amplifier cells 2230, 2232, 2234 level shift the entire chain of low-voltage amplifier cells 2230, 2232, 2234 without high-voltage isolation (such as optoisolators) along the feedforward connections 2210, 2214, 2216. At the same time, isolation, floating cells, and the feedforward connections enable the cascoded high-voltage amplifier 2200 with Class D-H preamplifier 2238 to avoid or minimize use of high-voltage components and high-voltage isolation for a cooler-running and more compact form factor than is known in the art. Furthermore, for linear signals the low-voltage amplifiers 2202, 2204, and 2206 can use Class D topologies for even further performance, size, and cooling advantages. What is more, by distributing amplification duties across N low-voltage amplifier cells, this disclosure more evenly achieves spatial distribution of thermal effects thereby avoiding hot spots in the cascoded high-voltage amplifier 2200. Yet, further, by removing optoisolators often associated with feedback circuits in high voltage applications, the disclosure removes delays associated with signals that have to pass through optoisolators, thus making the cascoded high-voltage amplifier 2200 with a Class D-H preamplifier 2238 more responsive to input signals and transients.

Each low-voltage amplifier cell 2230, 2232, 2234 can be configured to amplify an input voltage to that cell (in the case of all but the first low-voltage amplifier cell, this would be the output of the previous low-voltage amplifier cell). In some cases, all low-voltage amplifier cells 2230, 2232, 2234 can have the same gain, referred to as A. In other cases, different low-voltage amplifier cells 2230, 2232, 2234 may have different gains, for instance the first low-voltage amplifier cell 2230 can have a gain B and the remaining low-voltage amplifier cells 2232, 2234 can have the gain A. The gain A, whether equal to B or not, can equal 2. However, the gain A (and optionally B as well) can be greater than 2 and in some cases can be an exponential of 2 (i.e., 2^{C}, where C is a positive integer), such that A (and optionally B) can equal 2, 4, 8, 16, etc. In some embodiments, the gain A (and optionally B) can equal 2^{C} and can be less than a ratio of the output voltage over the input voltage. For instance, where the input voltage is 1V and the output voltage is 500V, C can be any positive integer such that 2^{C}<500/1 (i.e., C is a positive integer less than 9) and hence there could be up to 256 amplifying cells (2⁹). In other words, the first and second gain are equal to 2^{C} and less than the output voltage/the input voltage, where C is a positive integer. Regardless of the gain of each low-voltage amplifier cell 2230, 2232, 2234 or the number N of low-voltage amplifier cells, the serial topology of the low-voltage amplifier cells 2230, 2232, 2234 means that a common current is seen at the output of each low-voltage amplifier 2202, 2204, 2206.

The number N of low-voltage amplifier cells 2230, 2232, 2234 is not limited, but preferably will be equal to a total gain of the cascoded high-voltage amplifier 2200 divided by at least a maximum voltage to be seen across any given low-voltage amplifier cell 2230, 2232, 2234. However, in some embodiments, this same topology can apply to situations where some or all of the low-voltage amplifier cells may not be considered low voltage, for instance, where a voltage across each cell is 75V, or 250V, or some other higher valuer above 50V. Such a compromise of the low voltage nature may be worthwhile for higher output voltage embodiments of the cascoded high-voltage amplifier 2200 with Class D-H preamplifier 2238.

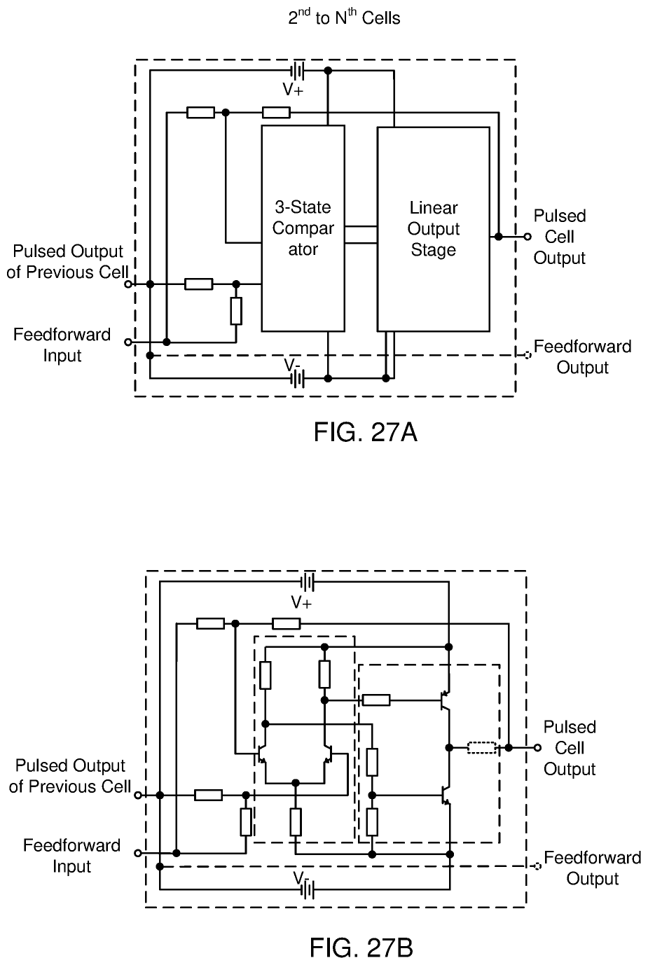

FIG. 22 presents the impedance components and low-voltage amplifiers in generalized form, and in some cases the impedance components can be implemented as resistors or resistor networks and the low-voltage amplifiers by op amps. The gain for each cell is selected via the balance of resistors in each resistor network. Reducing resistor values generally gives greater bandwidth but lower efficiency. The earth-referenced power bus 2250 may be referenced to voltage V₁ (e.g., ground) and thus may not need internal isolation structures such as a transformer. Although a transformer is one means of converting the earth-referenced power bus voltage to a voltage for use within each of the low-voltage amplifier cells 2230, 2232, 2234, other conversion topologies such as switching converters, etc. can also be used. Although op amps are one implementation of the low-voltage amplifiers 2202, 2204, 2206, other topologies are also possible, such as those using discrete transistor-based amplifiers shown for example in FIG. 27.

A DC-DC converter can bias each of the low-voltage amplifiers 2202, 2204, and 2206. These converters can be isolated from an earth-referenced power bus. For instance, each DC-DC converter can use a transformer to both down convert voltage from the earth-referenced power bus 2250 as well as provide isolation from the ‘high-voltage’ side of the isolation boundary (it should be noted that the earth-referenced power bus 2250 may also be low voltage).

For the purposes of clarity, one will note that the gain of a low-voltage amplifier cell and the gain of a low-voltage amplifier are different. For instance, the gain of each low-voltage amplifier cell can be 2, and the gain of each low-voltage amplifier depends on the low-voltage amplifier in question.

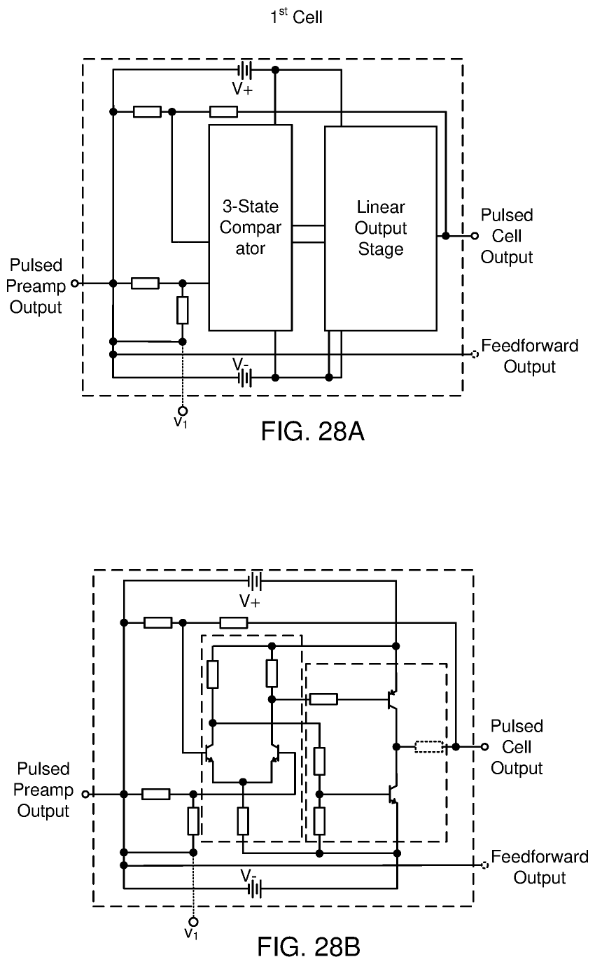

Turning to FIG. 23, is an embodiment of an amplifier that converts a low voltage pulsed input signal to a high-voltage pulsed output signal using a Class D-H preamplifier feeding a cascoded high-voltage amplifier having N series-coupled low-voltage amplifiers (the power stage also being referred to as a voltage-controlled voltage source amplifier (VCVS)). FIG. 23 uses a Class D-H preamplifier 2338 that applies gain without a PWM conversion. Details of an embodiment of such a Class D preamplifier 2338 can be seen for instance in FIG. 21. The variable rails and blending between D and H modes is the same as previously described. Further, the variable rails are infinitely variable, unlike traditional Class H amplifiers. The cascoded high-voltage amplifier 2300 does not include a filter(s) since the pulsed signal does not need digitizing. Interestingly, while the low-voltage amplifiers for linear signals described in FIG. 22 are switching or Class D, the low-voltage amplifiers for pulsed signals in FIG. 23 are high-speed linear. For instance, FIGS. 27 and 28 provide detailed examples of high speed linear low-voltage amplifiers that could be implemented in FIG. 23.

FIG. 24A illustrates an embodiment of a low-voltage amplifier cell such as the ones shown in FIG. 22 (e.g., 2230) for application to pulsed signals. This cell is configured to amplify a PWM signal, with a filter after the final cell used to linearize the amplified PWM. However, in other embodiment, a filter may be arranged after each cell, in which case, each cell takes a linear input and generates a PWM while applying gain and then linearizes the cell output before passing a linear signal to the next cell. FIG. 24A shows the variation where a single filter at the end of a chain of cells is implemented, and thus the Class D power amplifier passes a PWM signal without conversion. In particular, this example shows a low-voltage amplifier cell that could be arranged between other low-voltage amplifier cells, such as the second low-voltage amplifier cell 2230 in FIG. 22, though the teachings of this figure could easily be applied by one of skill in the art to a first or last (or N^{th}) low-voltage amplifier without undue experimentation. The cell includes a feedforward input from a previous cell and optionally a feedforward output to a next cell (not needed if this is the final of N^{th} cell). The Class D power amplifier has two inputs, one being a combination of the PWM from the previous cell and a feedforward PWM from the input of the previous cell, and the second input being feedback from the output of the Class D power amplifier. By operating as a switching or Class D amplifier, this cell can be smaller, run cooler, and use less power than the linear cells described earlier in this disclosure. FIG. 25A shows a similar topology, but modified for the first cell in the chain. Note that FIG. 25A has an input referenced to V₁, ground in some instances, and a feedforward output, but no feedforward input.

FIG. 24B illustrates an embodiment of details of the Class D power amplifier in FIG. 24A in situations where each low-voltage amplifier cell is followed by a filter. The Class D power amplifier can comprise a PWM converter for converting a linear input signal to a PWM output signal, where gain may or may not be applied during this conversion. The PWM signal can then be amplified via a switched output stage to provide an amplified PWM output. The PWM converter and switched output stages can both be powered by high and low elements of a power supply or DC-DC converter as previously described. The PWM converter can have two inputs-one is a voltage divided input from the feedforward connection to an input of a previous cell and an output of a previous cell; the other is feedback from the output of the switched output stage. In this variation, the PWM output is filtered before being passed to a next cell. Thus, FIGS. 24A and 24B help to show how internals of the low-voltage amplifier cells may be modified to accommodate different filtering topologies in the power stage. Furthermore, FIG. 25B shows a similar topology for a corresponding first low-voltage amplifier cell in the chain.

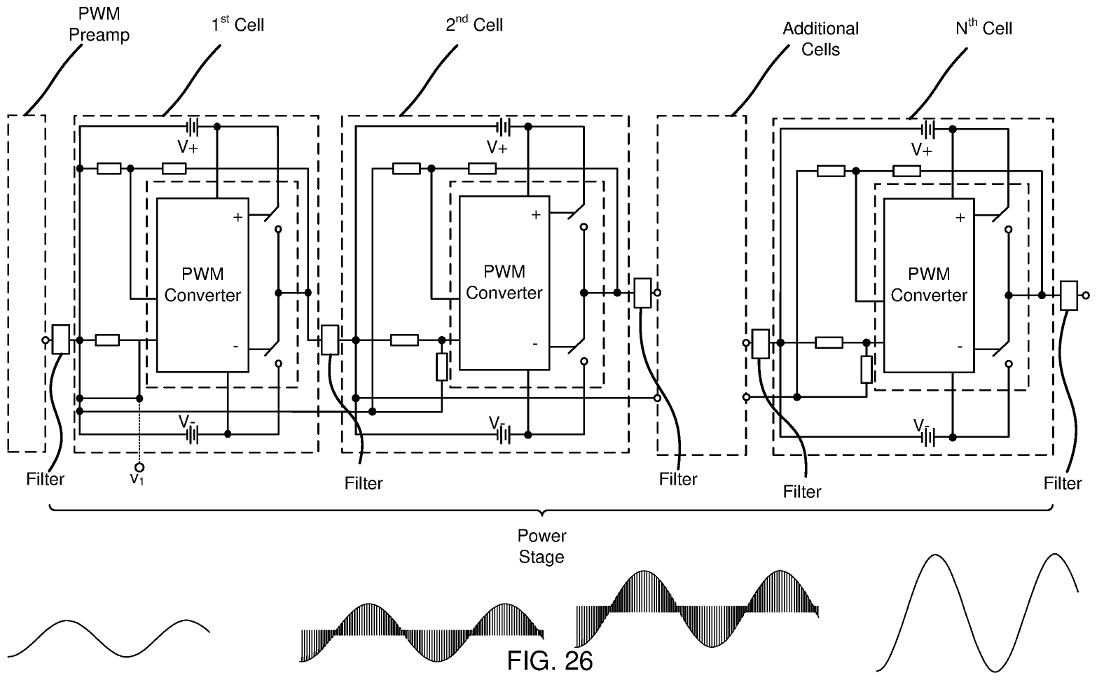

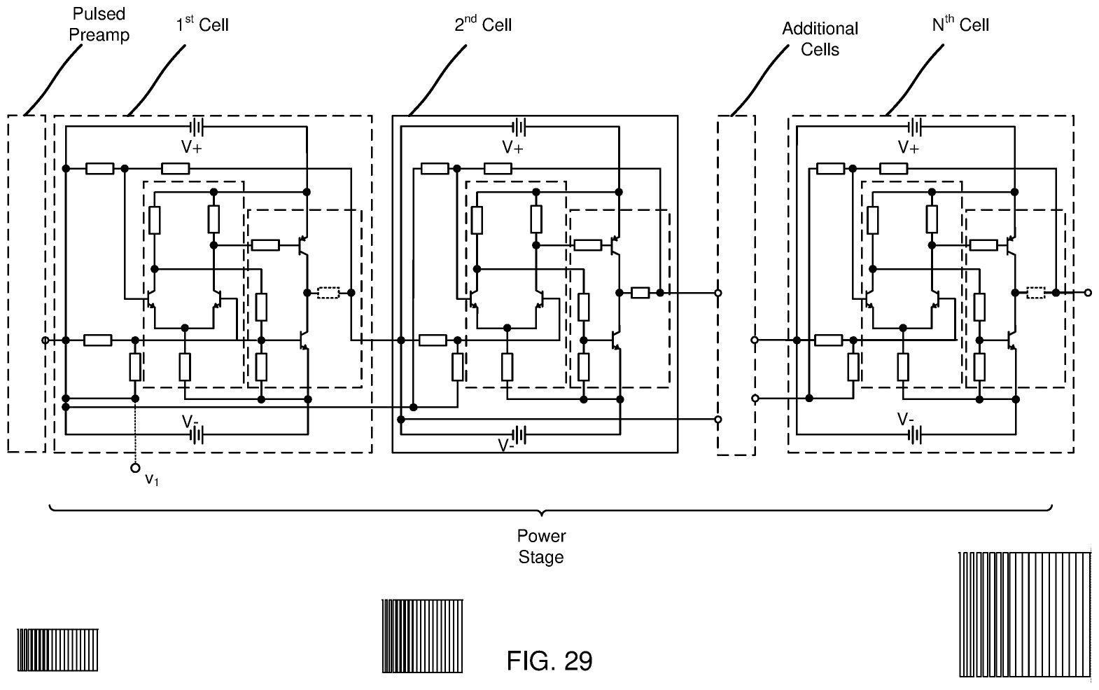

FIG. 26 illustrates an embodiment of an amplifier having a Class D-H preamplifier and a power stage comprising aspects of FIGS. 24 and 25 for linear signals. A PWM preamplifier as described previously in this disclosure (e.g., FIGS. 10, 11, and 20) can be coupled to a power stage, comprising two or more low-voltage amplifying cells. As illustrated, there is a first cell, a second cell, an N^{th} or last cell, and optionally one or more additional cells between the 2^{nd} and the N^{th} cells. The first cell has an input formed from a combination of the PWM preamplifier output and a reference voltage, V₁, that may be ground in some instances. This same reference voltage, V₁, is also the feedforward voltage to the 2^{nd} cell's input. The output of the 1^{st} cell is provided as the feedforward voltage to an input of a next cell after the 2^{nd}. An output of the N^{th} cell is an output of the power stage as well as of the entire amplifier. The illustrated embodiment is configured for handling linear waveforms and thus each low-voltage amplifier uses a PWM converter followed by a switching output stage. A filter linearizes the output of the Class D-H preamplifier as well as of each cell, though in some embodiments, a single filter at the amplifier output could be used (e.g., see FIG. 22). Where a single output filter is used, the low-voltage amplifiers would not need to include a PWM converter. With some minor modifications, this system can handle pulsed signals (see FIG. 29), for instance, by replacing each PWM converter with a three-state comparator and removing the filters at the output of each cell.

FIG. 27A illustrates an embodiment of a low-voltage amplifier cell such as the ones shown in FIG. 23 (e.g., 2304) for application to pulsed signals. The cell includes a three-state comparator with a Class AB linear output stage and a resistor network biasing the three-state comparator. The cell includes a feedforward input from a previous cell and optionally a feedforward output to a next cell (not needed if this is the last cell). The three-state comparator has two inputs and provides two outputs that are differentially amplified by the linear output stage to provide a single pulsed output. FIG. 28A shows a similar topology, but modified for the first cell in the chain. Note that FIG. 28A has an input referenced to V₁, ground in some instances, and a feedforward output, but no feedforward input. The three-state comparator preferably employs transistors having a switching speed that is commensurate with a switching speed of switches in the Class D-H preamplifier. For instance, MOSFETs can be employed, though JFETs may also be used with some loss of speed and efficiency, but with an increase in linearity and accuracy.

FIG. 27B illustrates an embodiment of a low-voltage amplifier cell such as the ones shown in FIG. 23 (e.g., 2304) for application to pulsed signals. In particular, this example shows a low-voltage amplifier cell that could be arranged between other low-voltage amplifier cells, such as the second low-voltage amplifier cell 2304 in FIG. 23, though the teachings of this figure could easily be applied by one of skill in the art to a first or last (or N^{th}) low-voltage amplifier without undue experimentation. For instance, for the last or N^{th} low-voltage amplifier, the optional feedforward is not used. FIG. 27B shows that the low-voltage amplifier can be embodied by discrete components, such as transistors as shown in this differential pair example. In particular, the cell's feedback loop is provided to the inverting input and the pulsed output from the previous cell along with feedforward from a previous cell, via a voltage divider, are provided to the non-inverting input of the three-state comparator. The three-state comparator has first and second transistors (e.g., JFETs for linearity and speed or MOSFETs where speed and efficiency are paramount). The first and second transistors are biased through impedance components by a high signal from a DC-DC positive portion of a power supply or DC-DC converter that provides isolation from an earth-referenced power bus. The two inputs to the three-state comparator control gates of the transistors and thereby control an amount of current drawn through each transistor and provided to a low input of the power supply or DC-DC converter. An output for each transistor can be taken from the drains, and further amplified by a linear output stage comprising two additional transistors (e.g., JFETs or MOSFETs) in a Class AB arrangement. The pair of output transistors are linear devices that are biased by the high and low outputs of the power supply or DC-DC converter. The output stage optionally includes an impedance between a node between the output transistors and the feedback node.

The low-voltage amplifier cell also includes two feedforward connections. The first of these couples an input of a previous low-voltage amplifier cell to a first input of the low-voltage amplifier. The second and optional feedforward connection couples the input of the low-voltage amplifier cell to a next low-voltage amplifier cell (unless this is the last or N^{th} low-voltage amplifier cell). Furthermore, FIG. 28B shows a similar topology for a corresponding first low-voltage amplifier cell in the chain.

FIG. 29 illustrates an embodiment of the amplifier having a power stage comprising aspects of FIGS. 27 and 28. A Class D-H preamplifier configured to handle pulsed signals as described previously in this disclosure (e.g., FIGS. 12, 13, and 21) can be coupled to a power stage, comprising two or more low-voltage amplifying cells also configured to handle pulsed signals. As illustrated, there is a first cell, a second cell, an N^{th} or last cell, and optionally one or more additional cells between the 2^{nd} and the N^{th} cells. The first cell has an input formed from a combination of the pulsed preamplifier output and a reference voltage, V₁, that may be ground in some instances. This same reference voltage, V₁, is also the feedforward voltage to the 2^{nd} cell's input. The output of the 1^{st} cell is provided as the feedforward voltage to an input of a next cell after the 2^{nd}. An output of the N^{th} cell is an output of the power stage as well as of the entire amplifier. The illustrated embodiment is configured for handling pulsed waveforms and thus each low-voltage amplifier uses a three-state comparator followed by a switching output stage. The three-state comparator allows linear operation of the switches therein, though biased like switching transistors, while also enabling a 0V output (hence the three-state output). This effectively allows the efficiency of a switched amplifier, but the ability to produce a 0V output, often demanded by power amplifier users, thereby providing additional efficiency gains over traditional switched topologies. Additionally, the linear transistors allow the low-voltage amplifiers to not only reproduce the pulses passing therethrough, but also to track the rise and falling edges of each pulse, thereby providing a more accurate reproduction of the input pulsed signal than Class D amplification.

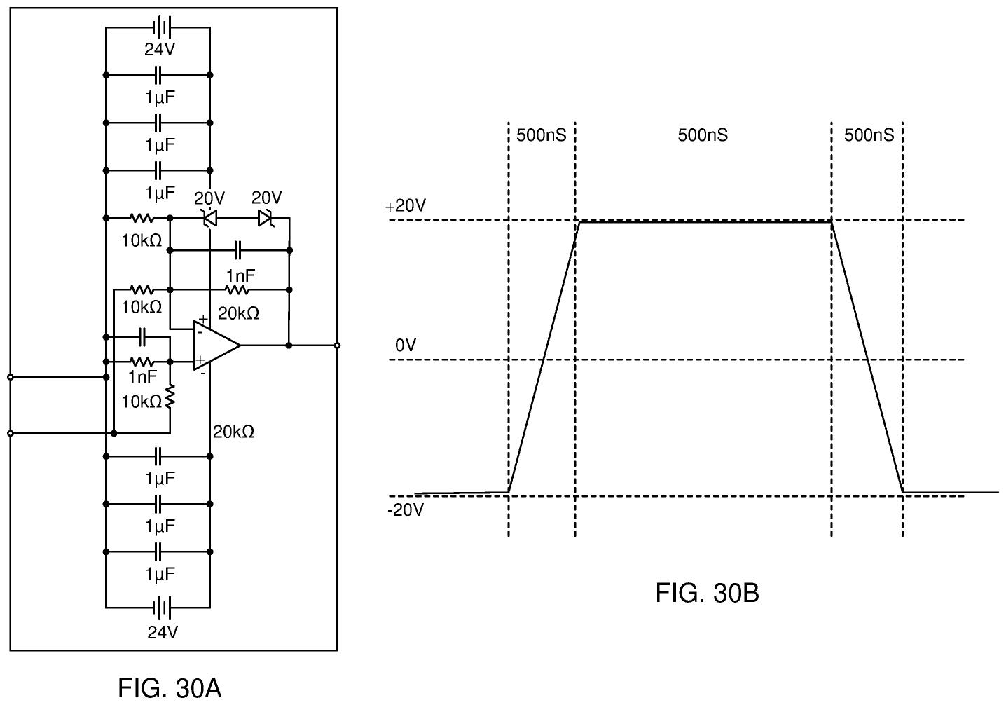

This disclosure describes high speed linear amplifiers of which there are many topologies to achieve this goal. FIG. 30A illustrates just one example, and this high speed linear amplifier can be implemented as the low-voltage amplifiers 2202, 2204, 2206, 2302, 2304, and 2306, for instance. Additional capacitors in parallel to the positive and negative power supplies or rails, along with opposing Zener diodes, help to improve switching speed. The illustrated values are exemplary only and should not be considered limiting. FIG. 30B shows an exemplary timing chart associated with switching of the low-voltage amplifier (FIG. 30A) output.

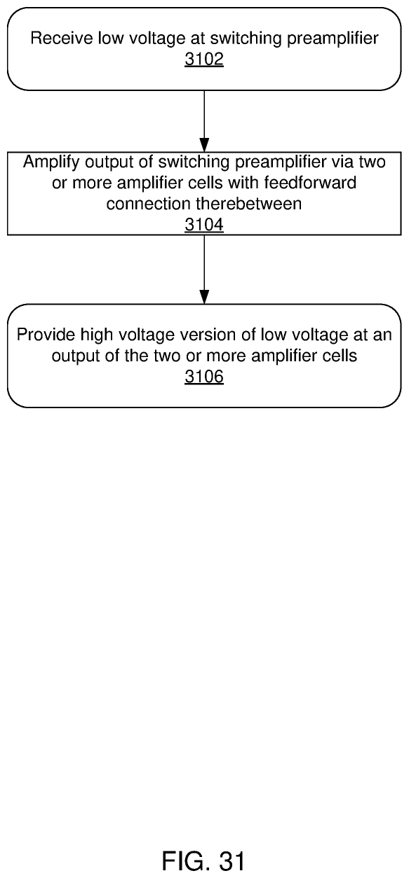

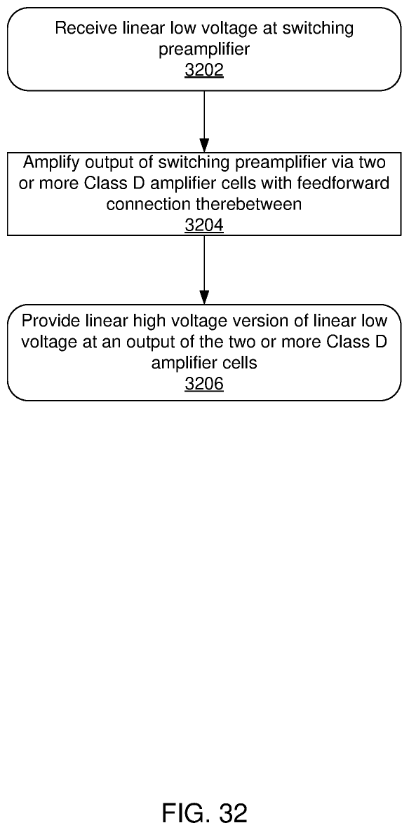

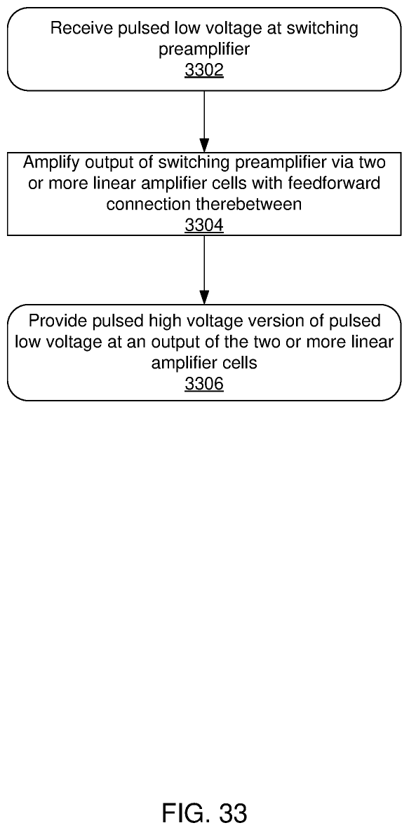

FIG. 31 illustrates a method of operating an amplifier with a Class D or Class D-H preamplifier, such as those described throughout this disclosure. The method can include receiving a low voltage (e.g., less than 50V) at a switching preamplifier (Block 3102), such as a Class D amplifier. In some embodiments, the switching preamplifier can be a Class D-H preamplifier configured to selectively operate as a Class D, Class H, or amplifier blending these two classes of amplification. The method can further include amplifying an output of the switching preamplifier via two or more amplifier cells with a feedforward connection therebetween (Block 3104). The method can further include providing a high voltage version (e.g., above 100V) of the low voltage at an output of the two or more amplifier cells (Block 3106). The method can be applied to linear signal (e.g., see FIG. 32) or pulsed signals (e.g., see FIG. 33).

FIG. 32 illustrates a method of operating an amplifier with a Class D or Class D-H preamplifier for linear signals. The method can include receiving a linear low voltage (e.g., less than 50V) at a switching preamplifier (Block 3202), such as a Class D amplifier that performs a PWM conversion of the linear signal. In some embodiments, the switching preamplifier can be a Class D-H preamplifier configured to selectively operate as a Class D, Class H, or an amplifier blending these two classes of amplification. A filter at an output of the preamp may linearize the PWM output of the preamplifier. The method can further include amplifying an output of the switching preamplifier via two or more Class D amplifier cells with a feedforward connection therebetween (Block 3204). Each of these Class D amplifier cells may be followed by a filter to linearize their PWM outputs. The method can further include providing a linear high voltage version (e.g., above 100V) of the linear low voltage at an output of the two or more Class D amplifier cells (Block 3206).

FIG. 33 illustrates a method of operating an amplifier with a Class D or Class D-H preamplifier for pulsed signals. The method can include receiving a pulsed low voltage (e.g., less than 50V) at a switching preamplifier (Block 3302), such as a Class D amplifier. In some embodiments, the switching preamplifier can be a Class D-H preamplifier configured to selectively operate as a Class D, Class H, or an amplifier blending these two classes of amplification. The method can further include amplifying an output of the switching preamplifier via two or more linear amplifier cells with a feedforward connection therebetween (Block 3304). The method can further include providing a pulsed high voltage version (e.g., above 100V) of the pulsed low voltage at an output of the two or more linear amplifier cells (Block 3306). In some embodiments, the linear amplifier cells can comprise a three-state comparator and a switching output stage, such as a Class AB output stage.

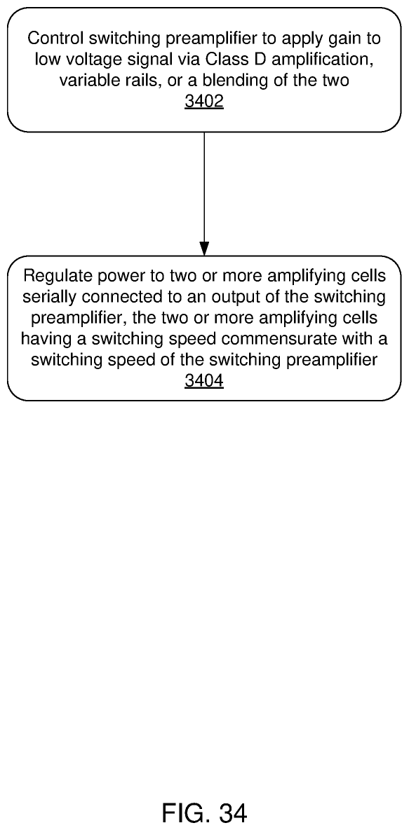

FIG. 34 illustrates a method of operating an amplifier with a Class D or Class D-H preamplifier and may be embodied in a non-transitory, tangible computer readable storage medium, encoded with processor readable instructions to perform a method for amplification. The method can include controlling a switching amplifier to apply gain to a low voltage signal via Class D amplification, variable rails, or a blending of the two (Block 3402). For instance, a performance mode selector can be controlled to set the blending of D and H modes in the preamplifier. The method can further include regulating power to two or more amplifying cells serially connected to an output of the switching preamplifier, where the two or more amplifying cells have a switching speed that is commensurate with a switching speed of the switching preamplifier (Block 3404). The two or more amplifying cells can be part of a VCVS high-voltage amplifier as described throughout this disclosure, and in particular, as described relative to FIGS. 22, 23, 26, and 29.

FIG. 35 illustrates an embodiment of a Class D-H amplifier that can be implemented as a power amplifier or a preamplifier. The Class D-H amplifier 3500 includes two variable sources 3502, 3504 providing variable rails to a Class D amplifier 3506. The input signal feeds the Class D amplifier 3506 as well as controls the variable sources 3502, 3504. Thus, the variable sources 3502, 3504 track the input signal, and as a result, the Class D amplifier 3506 has rail voltages that track the input signal. Optionally, the variable sources 3502, 3504 can be controlled by performance mode selectors 3508 and 3510 that dictate whether the variable sources 3502, 3504 provide a fixed or variable rail, and if a variable rail is provided, how much the rail varies (i.e., how much blending there is between the D and H modes). Additionally, the performance mode selectors 3508 and 3510 can cause a bottom of the PWM pulses to clamp to 0V, as seen for instance in FIG. 17. The Class D-H amplifier 3500 is configured to handle linear or pulsed input signals, with optional PWM converter 3512 being arranged upstream of the Class D amplifier when the input signal is linear. For pulsed input signals, the optional PWM converter 3512 can be excluded. The variable sources 3502, 3504 may take many forms such as, but not limited to, op amps with their own fixed rails.

Throughout this disclosure, the power stage, or VCVS amplifier, has been shown and described serially. This is optimal for high voltage output, but where a high current output is desired, the power stage can use a parallel configuration of cells.

The terms and expressions employed herein are used as terms and expressions of description and not of limitation, and there is no intention, in the use of such terms and expressions, of excluding any equivalents of the features shown and described or portions thereof. Each of the various elements disclosed herein may be achieved in a variety of manners. This disclosure should be understood to encompass each such variation, be it a variation of an embodiment of any apparatus embodiment, a method or process embodiment, or even merely a variation of any element of these. Particularly, it should be understood that the words for each element may be expressed by equivalent apparatus terms or method terms-even if only the function or result is the same. Such equivalent, broader, or even more generic terms should be considered to be encompassed in the description of each element or action. Such terms can be substituted where desired to make explicit the implicitly broad coverage to which this invention is entitled.

As but one example, it should be understood that all action may be expressed as a means for taking that action or as an element which causes that action. Similarly, each physical element disclosed should be understood to encompass a disclosure of the action which that physical element facilitates. Such changes and alternative terms are to be understood to be explicitly included in the description.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

### Additional Embodiments

One aspect of the disclosure is a cascoded high-voltage amplifier including a voltage input, a first variable DC source, a second variable DC source, and some number of additional variable DC sources up to an N^{th} variable DC source. Details of this embodiment can be described with reference to FIG. 3. The voltage input 120 can be configured to receive an input voltage, for instance, from the voltage source 101. The first variable DC source 102 can be coupled to the voltage input 120 via first input, for instance, through a resistive device such as 107 that may be part of a voltage divider comprising 107 and 124. The first variable DC source 102 can have a first output. The first variable DC source 102 can have a first gain. It can also be configured to amplify the input voltage and to provide an amplified version of the input voltage and the first output. The second variable DC source 104 can be configured to amplify the first output. The N^{th} variable DC source 106 can be configured to amplify an output of an N^{th}-1 variable DC source and to output a high-voltage version of the input voltage at an output 122. The output 122 can be configured for coupling to a load 103. N can be the number of variable DC sources in the cascoded high-voltage amplifier 100. Feedforward connections 110, 114, 116 between adjacent ones of the variable DC sources 102, 104, 106 can level shift subsequent variable DC sources without high-voltage signal isolation along the feedforward connections 110, 114, 116. Traditional amplifying cells typically have an optical isolator or other high-voltage isolating device along any feedback connections spanning different amplifier cells. Such devices add to the cost and complexity of an amplifier and increase latency. Here, because the voltage across any one of the cells 130, 132, 134 is low (e.g., less than 50V), the feedforward connections 110, 114, 116 can be free of high-voltage isolating devices such as optical isolators.

In some instances, the gain of each of the variable DC sources is equal, and in some cases can be substantially 2. The output voltage, or high-voltage version of the input voltage, is N*A times the input voltage, wherein N is the number of variable DC sources in the cascoded high-voltage amplifier, and wherein A is the gain of each variable DC source. To maintain isolation of the various cells 130, 132, 134, they are also isolated from a power supply 140 and more specifically, powered by voltage sources that are isolated from ground, for instance, via the isolation devices shown in FIG. 3. These isolation devices are transformers in one embodiment, but are not limited to this one example of an isolation device. In some embodiments, the first variable DC source is a voltage buffer or other circuit with a gain of 1, and all other variable DC sources are amplifiers such as op amps. In other embodiments, all of the variable DC sources are amplifiers such as op amps.

One aspect of the disclosure is a cascoded high-voltage amplifier comprising N amplifier cells, a voltage input, and a high voltage output. The N amplifier cells can each have a gain of A. The voltage input can be configured to receive an input voltage. The high voltage output can be configured to provide an N*A times amplified version of the input voltage. A first of the N amplifier cells can take a voltage divided version of the input voltage as one of two inputs. The second amplifier cell can comprise a first input having a first input voltage formed by a first voltage divider that couples to an output of the first amplifier cell and ground, a second input having a second input voltage formed by a second voltage divider that couples to an output of the second amplifier cell and ground. A third amplifier cell can comprise a third input having a third input voltage formed by a third voltage divider that couples to an output of the first amplifier cell and an output of the second amplifier cell, and a fourth input having a fourth input voltage formed by a fourth voltage divider that couples an output of the third amplifier cell and an output of the first amplifier cell. A N^{th} amplifier cell provides the high voltage output.

Another aspect of the disclosure is a cascoded high-voltage amplifier comprising a chain of voltage-controlled voltage sources, the amplifier comprising a voltage input, a first voltage-controlled voltage source, and an N-1 voltage-controlled voltage sources. The voltage input is configured to receive a ground-referenced input signal. The first voltage-controlled voltage source is coupled to the ground-referenced input signal and configured to generate an amplified version of the ground-referenced input signal. The N-1 voltage-controlled voltage sources form a voltage-stepped-chain with the first voltage-controlled voltage source, each producing a level-shifted version of an output of a previous one of the voltage-controlled voltage sources. Level shifting results from a low-voltage feedforward between inputs of adjacent ones of the voltage-controlled voltage sources, The voltage-controlled voltage sources have substantially equal gain A. the high-voltage at the output of the amplifier can be equally split between the N cells or N voltage-controlled voltage sources. Each of the voltage-controlled voltage sources, except the first, are powered by an earth-referenced power supply or a regulated power supply that is isolated from its power source. The first voltage-controlled voltage source can have a grounded power supply. The first voltage-controlled voltage source has an input coupled to ground whereas the N-1 voltage-controlled voltage sources are floating.

In some aspects, the first and second amplifying cells each may comprise at least one switch having a switching speed substantially the same as a switching speed of the at least a pair of switches in the switched preamplifier. In this way, the power amplifier can operate as a linear amplifier yet amplify the signal of a switching preamplifier. Although switching power amplifiers have been known to receive linearly amplified preamplifier signals, the reverse is not known in the art.

In some cases, the first feedforward connection may include an impedance component configured to control a gain of the second amplifying cell. This impedance component may be a resistor, a capacitor, an inductor, or any other suitable component that can provide an impedance to the signal passing through the feedforward connection. The impedance provided by this component may be used to control the gain of the second amplifying cell, potentially providing precise control over the amplification process. For instance, by adjusting the impedance of the component, the gain of the second amplifying cell may be increased or decreased as desired, allowing for flexible control over the output of the amplifier.

In some embodiments, the power amplifier may further comprise a third through N^{th} amplifying cells. These additional one or more amplifying cells may be coupled to the second amplifying cell and may be configured to amplify an output of the second amplifying cell. The inclusion of a third or more amplifying cells may provide additional stages of amplification, potentially enhancing the overall gain and output power of the amplifier, or reducing an amplification load on each cell.

In some cases, the third amplifying cell may have a second feedforward connection between the second amplifying cell and the third amplifying cell. In some aspects, the second feedforward connection may include an impedance component configured to control a gain of the third amplifying cell. This impedance component may be a resistor, a capacitor, an inductor, or any other suitable component that can provide an impedance to the signal passing through the feedforward connection. The impedance provided by this component may be used to control the gain of the third amplifying cell, potentially providing precise control over the amplification process. For instance, by adjusting the impedance of the component, the gain of the third amplifying cell may be increased or decreased as desired, allowing for flexible control over the output of the amplifier.

In some aspects, the first amplifying cell and the second amplifying cell of the power amplifier may each be configured to amplify the output of the preamplifier by a gain of at least 2. This high gain may allow for efficient amplification of low voltage signals to high voltage outputs. For instance, a low voltage input signal to the preamplifier may be amplified by the first amplifying cell by a first gain, and then further amplified by the second amplifying cell by a second gain, resulting in a high voltage output signal from the power amplifier. The specific gains of the first and second amplifying cells may be adjusted based on the requirements of the specific application, such as the desired output voltage or power level. In some cases, the first and second gain are the same.

In some aspects, the switched preamplifier may comprise at least a pair of switches in parallel. This configuration may allow for efficient switching of the input signal, potentially improving the performance of the amplifier. The switches may be configured to turn on and off in sync with each other, ensuring that the input signal is accurately represented in the output of the preamplifier. The specific configuration and operation of the switches may be determined based on the requirements of the specific application, such as the desired switching speed or the characteristics of the input signal.

In some cases, the switched preamplifier in the amplifier may comprise variable rails. These variable rails may allow for flexible control over the voltage levels within the preamplifier, potentially enhancing the efficiency and performance of the amplifier. The variable rails may be adjusted based on the input signal, allowing for dynamic control over the amplification process. For instance, when the input signal is at a high level, the voltage of the variable rails may be increased to provide a higher gain. On the other hand, when the input signal is at a low level, the voltage of the variable rails may be decreased to provide a lower gain. This dynamic adjustment of the voltage of the variable rails may allow for real-time control over the gain of the preamplifier, potentially improving the performance of the amplifier in response to changes in the input signal or operating conditions.

In some embodiments, the switched preamplifier may include a control circuit configured to adjust the voltage of the variable rails based on the input signal. This control circuit may be further configured to adjust the voltage of the variable rails in response to a change in the input signal, providing dynamic control over the amplification process. This dynamic adjustment of the voltage of the variable rails may allow for real-time control over the gain of the preamplifier, potentially improving the performance of the amplifier in response to changes in the input signal or operating conditions.

In some embodiments, the switches in the preamplifier and/or the first and second amplifying cells may be of any suitable type, such as mechanical switches, solid-state switches, or any other type of switch that can control the flow of current. The specific type and configuration of the switches may be determined based on the requirements of the specific application, such as the desired switching speed, the characteristics of the input signal, or the operating conditions of the amplifier. However, in an embodiment, the switches in the first and second amplifying cells can be MOSFETs or switches having similar or faster switching speeds.

In some embodiments, a common current passes through the first and second amplifying cells.

In some embodiments, a voltage across either of the first and second amplifying cells may be less than or equal to 50 volts. This voltage limit may help to protect the amplifying cells from damage due to overvoltage conditions, potentially enhancing the reliability and lifespan of the amplifier. The voltage limit may also help to reduce power dissipation and heat generation in the amplifying cells, potentially enhancing the efficiency of the amplifier. Lastly, this voltage limit may avoid the need for safety mechanisms and systems associated with high-voltage operation through all but the output of the amplifier.

In some embodiments, a Class D-H amplifier or preamplifier is provided. The Class D-H amplifier or preamplifier receives a low voltage input signal that is fed to a Class D or switching amplifier as well as two variable sources that track the input signal and provide variable rail voltages to power the Class D or switching amplifier. Thus, the Class D or switching amplifier provides a pulsed output with a variable amplitude, the variable amplitude governed by variation in the rail voltages. The variable sources can be controlled by performance mode selectors that dictate whether the variable sources provide a fixed or variable rail. If a variable rail is provided, the performance mode selectors dictate how much the rail varies. Additionally, the performance mode selectors can cause a corresponding one of the two variable sources to clamp to 0V when that variable source otherwise would go negative while tracking the input signal. The Class D-H amplifier or preamplifier is configured to handle linear or pulsed input signals, with an optional PWM converter being arranged upstream of the Class D amplifier when the input signal is linear.

What is claimed is:

1. An amplifier comprising:
a switched preamplifier; and
a power amplifier comprising:
a first amplifying cell and a second amplifying cell, wherein the first amplifying cell is coupled between the switched preamplifier and the second amplifying cell.

2. The amplifier of claim 1, further comprising a feedforward connection between the first amplifying cell and the second amplifying cell.

3. The amplifier of claim 2, wherein the feedforward connection is between an input of the first amplifying cell and an input of the second amplifying cell, and wherein the first and second amplifying cells are low voltage.

4. The amplifier of claim 1, wherein the switched preamplifier comprises variable rails configured to track an input to the switched preamplifier.

5. The amplifier of claim 1, wherein the switched preamplifier is configured to operate as a Class D, Class H, or blended D-H amplifier.

6. The amplifier of claim 1, wherein the first amplifying cell is coupled to a power regulator that is isolated from a power source.

7. The amplifier of claim 1, wherein the switched preamplifier has a voltage input below 50 volts and the power amplifier has a voltage output above 100 volts.

8. The amplifier of claim 7, wherein a voltage across either of the first and second amplifying cells is less than or equal to 50 volts.

9. The amplifier of claim 1, wherein the switched preamplifier comprises a switched pair output stage and wherein the first and second amplifying cells each comprise at least one switch having a first switching speed substantially the same or greater than a second switching speed of the switched pair output stage in the switched preamplifier.

10. The amplifier of claim 1, wherein the amplifier is configured to receive a low voltage pulsed input and generate a high voltage pulsed output.

11. The amplifier of claim 10, wherein the first and second amplifier cells comprise linear switching devices.

12. The amplifier of claim 1, wherein the amplifier is configured to receive a low voltage linear input and generate a high voltage linear output, and wherein the switched preamplifier and the first and second amplifying cells are Class D.

13. The amplifier of claim 12, wherein a first filter is arranged after the second amplifying cell.

14. The amplifier of claim 13, wherein a second filter is arranged between the switched preamplifier and the first amplifying cell and a third filter is arranged between the first and second amplifying cells.

15. The amplifier of claim 1, wherein the power amplifier is configured to receive power from a low-voltage rail or low-voltage regulated power supply.

16. A method of operating an amplifier comprising:
receiving a low voltage at a switching preamplifier;
controlling rails of the switching preamplifier according to the low voltage; and
amplifying an output of the switching preamplifier to a high voltage via two or more low voltage amplifier cells.

17. The method of claim 16, further comprising selecting a blending of Class D and Class H amplifying modes in the switching preamplifier.

18. The method of claim 16, wherein:
the low voltage is pulsed and the two or more low voltage amplifier cells are linear; or
the low voltage is linear and the two or more low voltage amplifier cells are Class D.

19. The method of claim 18, further comprising converting the low voltage to a pulse-width modulated signal in the switching preamplifier and filtering an output of at least one of the two or more switching amplifier cells to provide a high-voltage linear amplifier output.

20. A non-transitory, tangible computer readable storage medium, encoded with processor readable instructions to perform a method for amplification, the method comprising:
controlling a switching preamplifier to apply gain to a low-voltage input signal via Class D amplification, variable rails, or a blending of the two; and
regulating power to two or more amplifying cells connected to an output of the switching preamplifier, the two or more amplifying cells having a first switching speed commensurate with or greater than a second switching speed of the switching preamplifier.
